(19) United States
(12) Patent Application Publication
(10) Pub. No.: US 2025/0113666 A1
(43) Pub. Date: Apr. 3, 2025

(54) A MICRO LED PANEL WITH RE-GROWTH LAYER AND MANUFACTURING METHOD THEREOF

(71) Applicant: Jade Bird Display (Shanghai) Limited, Pudong New Area, Shanghai (CN)

(72) Inventors: Yuankun ZHU, Shanghai (CN); Anle FANG, Shanghai (CN); Deshuai LIU, Shanghai (CN)

(73) Assignee: Jade Bird Display (Shanghai) Limited, Pudong New Area, Shanghai (CN)

(21) Appl. No.: 18/832,120

(22) PCT Filed: Jan. 31, 2022
(86) PCT No.: PCT/CN2022/075277

§ 371 Date: Jul. 23, 2024

(51) Int. Cl. H10H 20/821; H01L 25/075; H10H 20/812; H10H 20/825; H10H 29/80

(52) U.S. Cl. CPC H10H 20/821; H01L 25/0753; H10H 20/812; H10H 20/825; H10H 29/942

(57) ABSTRACT

A micro LED panel having a micro LED array and the system and method to manufacture the micro LED panel are provided. The micro LED array includes at least one micro LED structure. The micro LED structure at least includes: a mesa structure and a re-growth layer (04). The re-growth layer (04) is grown on at least part of the sidewall of the first type epitaxial layer (01) and on the whole sidewall of the light emitting layer (03), thereby decreasing the non-radiation recombination on the sidewall of the mesa structure and improving the light emitting efficiency.

### TECHNICAL FIELD

The present disclosure generally relates to light emitting diode (LED) technology and, more particularly, to a micro LED panel and a method of manufacturing the micro LED structure.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

Inorganic micro light emitting diodes are of increasing importance because of their use in various applications including self-emissive micro-displays, visible light communications and opto-genetics. The micro LEDs show higher output performance than conventional LEDs due to better strain relaxation, improved light extraction efficiency, and uniform current spreading. The micro LEDs also exhibit improved thermal effects, and operate at a higher current density, fast response rate, larger work temperature range, higher resolution, color gamut, and contrast and lower power consumption as compared with conventional LEDs.

To achieve higher pixel density, the size of the micro LEDs is reduced to less than 200 nm. However, the efficiency and the carrier lifetime of the micro LED array based device degrade drastically with the reduced micro LED size to a large extent, by surface recombination and poor p-type conduction induced by top-down etching. The performance of micro LEDs also suffers severely from quantum-confined stark effect, particularly due to the strain-induced polarization field, which leads to unstable operation, and significant variations in emission wavelengths with increasing current. Additionally, with the decrease of the micro LED diameter, a large number of surface states and defects are formed at the surface of the micro LED structure by Inductively Coupled Plasma (ICP) etching, which increases the non-radiation recombination at the surface of the micro LED structures.

Additionally, the emission of the conventional micro LED structure is mainly distributed at any direction which exhibits poor directional emission and reduces the light intensity along the vertical direction. To realize the directional emission of the micro LED structure, extra reflective structures are configured around the mesa of the micro LED structure and at the bottom of the mesa, so as to reflect the emission light to a same direction, which causes a complex manufacturing process and increases the cost of the micro LED.

Furthermore, in the micro LED array based device, one micro LED is conventionally used as one pixel such as in monolithic micro LED array panel. However, the micro LED structure with smaller diameter shows lower external quantum efficiency (EQE), which reduces the light efficiency of each pixel.

The above content is only used to assist in understanding the technical solutions of the present application, and does not constitute an admission that the above is prior art.

### SUMMARY

There is a need for improved display designs that improve upon, and help to address the shortcomings of conventional display systems, such as those described above. In particular, there is a need for display panels with improved efficiencywith better images.

In order to overcome the drawback mentioned above, the present invention provides a micro LED panel, to improve the light emitting efficiency, to avoid crosstalk, to minimize the surface carrier loss, and to optimize the quantum well sidewall area.

To achieve the above objectives, some exemplary embodiments of the present disclosure providea micro LED panel having a micro LED array, comprising:
at least one micro LED structure, wherein the micro LED structure at least comprises:
a mesa structure, wherein the mesa structure from bottom to top comprises: a first type epitaxial layer and a light emitting layer;
a second type epitaxial layer, continuously formed on a top of the light emitting layer and continuously formed on a whole area of the micro LED panel; and,
a re-growth layer, grown on at least part of a sidewall of the first type epitaxial layer and a whole sidewall of the light emitting layer.

In some exemplary embodiments or any combination of exemplary embodiments of the micro-LED panel, a top end of the re-growth layer further extrudes along a top surface of the dielectric layer, and the second type epitaxial layer is formed on the top of the light emitting layer and a top of the re-growth layer.

In some exemplary embodiments or any combination of exemplary embodiments of the micro-LED panel, the re-growth layer on the sidewall of the light emitting layer is not parallel to an extending direction of the light emitting layer.

In some exemplary embodiments or any combination of exemplary embodiments of the micro-LED panel, an inclined angle of the re-growth layer on the sidewall of the light emitting layer is 30 degrees to 90 degrees relative to the extending direction of the light emitting layer; and the re-growth layer extruded along the dielectric layer is parallel to a top surface of the dielectric layer.

In some exemplary embodiments or any combination of exemplary embodiments of the micro-LED panel, the re-growth layer extruded along the top of the dielectric layer is connected to the adjacent light emitting layer and the first type epitaxial layer.

In some exemplary embodiments or any combination of exemplary embodiments of the micro-LED panel, the re-growth layer is further formed on a whole sidewall of the first type epitaxial layer and the light emitting layer.

In some exemplary embodiments or any combination of exemplary embodiments of the micro-LED panel, the re-growth layer is further formed on a bottom surface of the first type epitaxial layer.

In some exemplary embodiments or any combination of exemplary embodiments of the micro-LED panel, a diameter of the mesa structure is not more than 3 μm.

In some exemplary embodiments or any combination of exemplary embodiments of the micro-LED panel, the light emitting layer comprises a top surface, an edge surface and a bottom surface; and, the re-growth layer is grown on the edge surface of the light emitting layer and not grown on the top surface and the bottom surface of the light emitting layer.

In some exemplary embodiments or any combination of exemplary embodiments of the micro-LED panel, the light emitting layer comprises a plurality of pairs of quantum wells; and the re-growth layer on the sidewall of the light emitting layer is not parallel to each of the plurality of pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the re-growth layer with intrinsic doped ions is the same as material of the first type epitaxial layer and/or material of the second type epitaxial layer but without intentional extrinsic doping ions.

In some exemplary embodiments or any combination of exemplary embodiments of the micro-LED panel, material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal, material of the first epitaxial layer is monocrystal and material of the second epitaxial layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, the material of the dielectric layer is one or more of SiO₂, SiNx, Al₂O₃, AlN, HfO₂, TiO₂, and/or ZrO₂.

In some exemplary embodiments or any combination of exemplary embodiments of the micro-LED panel, the material of the first type epitaxial layer is one or more of GaAs, InGaAs, GaP, GaN, InGaN, AlGaN, AlInP, GaInP, and/or AlGaInP, and the material of the second epitaxial layer is one or more of GaAs, InGaAs, GaP, GaN, InGaN, AlGaN, AlInP, GaInP, and/or AlGaInP.

Some exemplary embodiments of the present disclosure provide a method of manufacturing the micro LED panel, comprising:
step 1, supplying a semiconductor substrate with an epitaxial structure, wherein the epitaxial structure comprises a first type epitaxial layer, a light emitting layer and a second type epitaxial layer from top down;
step 2, forming a mesa structure by patterning the first type epitaxial layer and the light emitting layer;
step 3, forming a re-growth layer on sidewall of the light emitting layer and on at least part of sidewall of the first type epitaxial layer by an epitaxial material re-growth process;
step 4, forming a dielectric layer on the re-growth layer and forming an opening in the dielectric layer on the first type epitaxial layer; and, forming a bottom contact in the opening on surface of the first type epitaxial layer;
step 5, forming a bottom connected structure in the opening;
step 6, bonding the first type epitaxial layer and the bottom connected structure with an IC backplane by turning the semiconductor substrate upside down; then, removing the semiconductor substrate; and
step 7, forming a top contact and a top conductive layer on the second epitaxial layer.

In some exemplary embodiments or any combination of exemplary embodiments of the method of manufacturing the micro-LED panel, in step 3, the re-growth layer is further formed on a whole sidewall and top of the first type epitaxial layer; in step 4, the opening is further formed in the re-growth layer on the first type epitaxial layer; and, temperature in the re-growth process is 400° C. to 1000° C., and re-growth time is 5 seconds to 1000 seconds.

In some exemplary embodiments or any combination of exemplary embodiments, the method of manufacturing the micro-LED panel further includes: in step 3, before forming the re-growth layer, forming a mask pattern covering a top and part of the sidewall of the first type epitaxial layer; and after forming the re-growth layer, removing the mask pattern.

Some exemplary embodiments of the present disclosure provide a micro LED panel, comprising:
a micro LED structure array comprising at least two micro LED structures, wherein each of the micro LED structure comprises:
a mesa structure, wherein the mesa structure from bottom to top comprises: a first type epitaxial layer and a light emitting layer;
a second type epitaxial layer, continuously formed on top of the light emitting layer and top of the re-growth layer, and continuously formed on whole area of the micro LED panel; and,
a re-growth layer, grown on whole sidewall of the first type epitaxial layer and whole sidewall of the light emitting layer and fully filled between the adjacent mesa structures.

In some exemplary embodiments or any combination of exemplary embodiments of the micro-LED panel, top width of the re-growth layer is the same as top width of the space between adjacent light emitting layers of adjacent micro LED structures.

In some exemplary embodiments or any combination of exemplary embodiments of the micro-LED panel, diameter of the mesa structure is not more than 3 μm.

In some exemplary embodiments or any combination of exemplary embodiments of the micro-LED panel, the light emitting layer comprises a top surface, an edge surface and a bottom surface; and, the re-growth layer is grown on the edge surface of the light emitting layer and not grown on the top surface and the bottom surface of the light emitting layer.

In some exemplary embodiments or any combination of exemplary embodiments of the micro-LED panel, the light emitting layer comprises a plurality of pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the re-growth layer with intrinsic doped ions is the same as material of the first type epitaxial layer and/or material of the second type epitaxial layer but without intentional extrinsic doping ions.

In some exemplary embodiments or any combination of exemplary embodiments of the micro-LED panel, the material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal, material of the first epitaxial layer is monocrystal and material of the second epitaxial layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, the thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, material of the first type epitaxial layer is one or more of GaAs, InGaAs, GaP, GaN, InGaN, AlGaN, AlInP, GaInP, and/or AlGaInP, and material of the second epitaxial layer is one or more of GaAs, InGaAs, GaP, GaN, InGaN, AlGaN, AlInP, GaInP, and/or AlGaInP.

In some exemplary embodiments or any combination of exemplary embodiments of the micro-LED panel, a bottom connected structure is formed in the re-growth layer below and electrically connected to the first type epitaxial layer.

Some exemplary embodiments of the present disclosure provide a method of manufacturing the micro LED panel, comprising:
step 1, supplying a semiconductor substrate with an epitaxial structure, wherein the epitaxial structure comprises a first type epitaxial layer, a light emitting layer and a second type epitaxial layer from top down;
step 2, forming a mesa structure by patterning the first type epitaxial layer and the light emitting layer; and, forming a bottom contact on the top of the mesa structure;
step 3, forming a re-growth layer fully filled in the space of the adjacent mesa structures and on whole sidewall of the light emitting layer and on whole sidewall of the first type epitaxial layer by an epitaxial material re-growth process;
step 4, forming an opening in the re-growth layer on the first type epitaxial layer;
step 5, forming a bottom connected structure in the opening;
step 6, bonding the bottom connected structure with an IC backplane by turning the semiconductor substrate upside down, and then, removing the semiconductor substrate; and,
step 7, forming a top contact and a top conductive layer on the second epitaxial layer.

In some exemplary embodiments or any combination of exemplary embodiments of the method of manufacturing the micro-LED panel, in step 3, temperature in the re-growth process is 400° C. to 1000° C., and re-growth time is 5 seconds to 1000 seconds.

Some exemplary embodiments of the present disclosure provide a micro LED panel, comprising:
a micro LED structure array comprising at least one micro LED structures, wherein the micro LED structure comprises:
a mesa structure, wherein the mesa structure from bottom to top comprises: a first type epitaxial layer and a light emitting layer;
a second type epitaxial layer, continuously formed on top of the light emitting layer and the re-growth layer, and continuously formed on whole area of the micro LED panel; and,
a re-growth layer, grown on part of the sidewall of the first type epitaxial layer and whole sidewall of the light emitting layer and filled between adjacent mesa structures.

In some exemplary embodiments or any combination of exemplary embodiments of the micro-LED panel, top width of the re-growth layer is the same as top space width between adjacent light emitting layers.

In some exemplary embodiments or any combination of exemplary embodiments, the micro-LED panel further includes a dielectric layer formed at the bottom of the re-growth layer.

In some exemplary embodiments or any combination of exemplary embodiments of the micro-LED panel, material of the dielectric layer is one or more of SiO₂, SiNx, Al₂O₃, AlN, HfO₂, TiO₂, and/or ZrO₂.

In some exemplary embodiments or any combination of exemplary embodiments of the micro-LED panel, a bottom connected structure formed in the dielectric layer below and electrically connected to the first type epitaxial layer.

In some exemplary embodiments or any combination of exemplary embodiments of the micro-LED panel, diameter of the mesa structure is not more than 3 μm.

In some exemplary embodiments or any combination of exemplary embodiments of the micro-LED panel, the light emitting layer comprises a top surface, an edge surface and a bottom surface; and, the re-growth layer is grown on the edge surface of the light emitting layer and not grown on the top surface and the bottom surface of the light emitting layer.

In some exemplary embodiments or any combination of exemplary embodiments of the micro-LED panel, the light emitting layer comprises a plurality of pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the re-growth layer with intrinsic doped ions is the same as material of the first type epitaxial layer and/or material of the second type epitaxial layer but without intentional extrinsic doping ions.

In some exemplary embodiments or any combination of exemplary embodiments of the micro-LED panel, material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal, material of the first epitaxial layer is monocrystal and material of the second epitaxial layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, the thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, material of the first type epitaxial layer is one or more of GaAs, InGaAs, GaP, GaN, InGaN, AlGaN, AlInP, GaInP, and/or AlGaInP, and material of the second epitaxial layer is one or more of GaAs, InGaAs, GaP, GaN, InGaN, AlGaN, AlInP, GaInP, and/or AlGaInP.

Some exemplary embodiments of the present disclosure provide a method of manufacturing the micro LED panel, comprising:
step 1, supplying a semiconductor substrate with an epitaxial structure, wherein the epitaxial structure comprises a first type epitaxial layer, a light emitting layer and a second type epitaxial layer from top down;
step 2, forming a mesa structure by patterning the first type epitaxial layer and the light emitting layer;
step 3, forming a re-growth layer on whole sidewall of the light emitting layer and on part of the sidewall of the first type epitaxial layer by an epitaxial material re-growth process;
step 4, forming a dielectric layer on the re-growth layer and forming an opening in the dielectric layer on the first type epitaxial layer; and, forming a bottom contact in the opening on surface of the first type epitaxial layer;
step 5, forming a bottom connected structure in the opening;
step 6, bonding the bottom connected structure with an IC backplane by turning the semiconductor substrate upside down; then, removing the semiconductor substrate; and
step 7, forming a top contact and a top conductive layer on the second epitaxial layer.

In some exemplary embodiments or any combination of exemplary embodiments of the method of manufacturing the micro-LED panel, in step 3, temperature in the re-growth process is 400° C. to 1000° C., and re-growth time is 5 seconds to 1000 seconds.

Some exemplary embodiments of the present disclosure provide a micro LED panel, comprising:
a micro LED structure array comprising at least one micro LED structure, wherein the micro LED structure comprises:
a mesa structure. wherein the mesa structure from bottom to top comprises: a first type epitaxial layer, a light emitting layer and a second type epitaxial layer; and a re-growth layer, grown on at least part of sidewall of the first type epitaxial layer and a whole sidewall of the light emitting layer.

In some exemplary embodiments or any combination of exemplary embodiments of the micro-LED panel, a dielectric layer is formed between the adjacent mesa structures; and the top end of the re-growth layer further extrudes into the dielectric layer.

In some exemplary embodiments or any combination of exemplary embodiments of the micro-LED panel, the re-growth layer extruded into the dielectric layer is connected to an adjacent light emitting layer and an adjacent first type epitaxial layer.

In some exemplary embodiments or any combination of exemplary embodiments of the micro-LED panel, the re-growth layer is grown on whole sidewall of the light emitting layer and whole sidewall of the first type epitaxial layer.

In some exemplary embodiments or any combination of exemplary embodiments of the micro-LED panel, the re-growth layer on the sidewall of the light emitting layer is not parallel to an extending direction of the light emitting layer.

In some exemplary embodiments or any combination of exemplary embodiments of the micro-LED panel, an inclined angle of the re-growth layer on the sidewall of the light emitting layer is 30 degrees to 90 degrees relative to an extending direction of the light emitting layer; the re-growth layer extruded into the dielectric layer is parallel to bottom surface of the second type epitaxial layer.

In some exemplary embodiments or any combination of exemplary embodiments of the micro-LED panel, diameter of the mesa structure is not more than 3 μm.

In some exemplary embodiments or any combination of exemplary embodiments of the micro-LED panel, the light emitting layer comprises a top surface, an edge surface and a bottom surface; and, the re-growth layer is grown on the edge surface of the light emitting layer and not grown on the top surface and the bottom surface of the light emitting layer.

In some exemplary embodiments or any combination of exemplary embodiments of the micro-LED panel, the light emitting layer comprises a plurality of pairs of quantum wells; and the re-growth layer on the sidewall of the light emitting layer is not parallel to each of the plurality of pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the re-growth layer with intrinsic doped ions is the same as material of the first type epitaxial layer and/or material of the second type epitaxial layer but without intentional extrinsic doping ions.

In some exemplary embodiments or any combination of exemplary embodiments of the micro-LED panel, material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal, material of the first epitaxial layer is monocrystal and material of the second epitaxial layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, the thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, the dielectric layer is formed on surface of the re-growth layer between adjacent mesa structures.

In some exemplary embodiments or any combination of exemplary embodiments of the micro-LED panel, material of the dielectric layer is one or more of SiO₂, SiNx, Al₂O₃, AlN, HfO₂, TiO₂, and/or ZrO₂.

In some exemplary embodiments or any combination of exemplary embodiments of the micro-LED panel, material of the first type epitaxial layer is one or more of GaAs, InGaAs, GaP, GaN, InGaN, AlGaN, AlInP, GaInP, and/or AlGaInP, and material of the second epitaxial layer is one or more of GaAs, InGaAs, GaP, GaN, InGaN, AlGaN, AlInP, GaInP, and/or AlGaInP.

Some exemplary embodiments of the present disclosure provide a method of manufacturing the micro LED panel, comprising:
step 1, supplying a semiconductor substrate with an epitaxial structure, wherein the epitaxial structure comprises a first type epitaxial layer, a light emitting layer and a second type epitaxial layer from top down;
step 2, forming a mesa structure by patterning the epitaxial structure;
step 3, forming a first mask pattern on the semiconductor substrate to cover sidewall of the first type epitaxial layer and sidewall of the light emitting layer;
step 4, depositing a first dielectric layer on the substrate between adjacent mesa structures, top of the first dielectric layer is aligned with bottom of the light emitting layer;
step 5, removing the first mask pattern;
step 6, forming a re-growth layer on the whole sidewall of the light emitting layer and on at least part of the sidewall of the first epitaxial layer by an epitaxial material re-growth process;
step 7, forming a second dielectric layer on the re-growth layer and forming an opening on the first type epitaxial layer; and, filling a bottom contact in the opening;
step 8, forming a bottom connected structure in the opening;
step 9, bonding the first type epitaxial layer and the bottom connected structure with an IC backplane by turning the semiconductor substrate upside down; then, removing the semiconductor substrate; and
step 10, forming a top contact and a top conductive layer on the second epitaxial layer.

In some exemplary embodiments or any combination of exemplary embodiments, the method of manufacturing the micro-LED panel further includes: in step 6, before forming the re-growth layer, forming a second mask pattern covering top and part of the sidewall of the first type epitaxial layer, wherein the re-growth layer is formed at whole sidewall of the light emitting layer and part of the sidewall of the first type epitaxial layer; and after forming the re-growth layer, removing the second mask pattern.

In some exemplary embodiments or any combination of exemplary embodiments of the method of manufacturing the micro-LED panel, in step 6, the re-growth layer is directly formed on whole sidewall of the light emitting layer, on whole sidewall of the first type epitaxial layer, and on top of the first type epitaxial layer.

In some exemplary embodiments or any combination of exemplary embodiments of the method of manufacturing the micro-LED panel, in step 6, temperature in the re-growth process is 400° C. to 1000° C., and re-growth time is 5 seconds to 1000 seconds.

Some exemplary embodiments of the present disclosure provide a method of manufacturing the micro LED panel, comprising:
step 1, supplying a semiconductor substrate with an epitaxial structure, wherein the epitaxial structure comprises a first type epitaxial layer, a light emitting layer and a second type epitaxial layer from top down;
step 2, forming a mesa structure by patterning the epitaxial structure;
step 3, forming a first mask pattern on the semiconductor substrate to cover sidewall of the second type epitaxial layer, wherein top of the first mask pattern is not higher than bottom of the light emitting layer;
step 4, forming a re-growth layer on sidewall of the light emitting layer and on at least part of sidewall of the first epitaxial layer by an epitaxial material re-growth process;
step 5, forming a first dielectric layer on the re-growth layer and forming an opening on the first type epitaxial layer; and, filling a bottom contact in the opening;
step 8, forming a bottom connected structure in the opening;
step 9, bonding the first type epitaxial layer and the bottom connected structure with an IC backplane by turning the semiconductor substrate upside down; then, removing the semiconductor substrate;
step 10, forming a second dielectric layer on the re-growth layer between the adjacent mesa structures; and
step 11, forming a top contact and a top conductive layer on the second epitaxial layer.

In some exemplary embodiments or any combination of exemplary embodiments, the method of manufacturing the micro-LED panel further includes: in step 4, before forming the re-growth layer, forming a second mask pattern covering the top and part of sidewall of the first type epitaxial layer, wherein the re-growth layer is formed at whole sidewall of the light emitting layer and part of the sidewall of the first type epitaxial layer; and after forming the re-growth layer, removing the mask pattern.

In some exemplary embodiments or any combination of exemplary embodiments of the method of manufacturing the micro-LED panel, material of the first mask pattern is different from material of the second mask pattern.

In some exemplary embodiments or any combination of exemplary embodiments of the method of manufacturing the micro-LED panel, in step 4, the re-growth layer is directly formed on whole sidewall of the light emitting layer, on whole sidewall of the first type epitaxial layer, and on top of the first type epitaxial layer.

In some exemplary embodiments or any combination of exemplary embodiments of the method of manufacturing the micro-LED panel, in step 4, temperature in the re-growth process is 400° C. to 1000° C., and re-growth time is 5 seconds to 1000 seconds.

The micro LED panel provided by the present disclosure can avoid the nonradiative recombination at the sidewalls of the micro LED structure. Furthermore, compared with the conventional micro LEDs, the micro LED structure of the present disclosure has a high directional emission, with no other reflective structure, thereby simplifying the micro LED structure and decreasing the cost. Furthermore, the present disclosure can also inhibit the non-radiation recombination at the surface of the micro LED structures, thereby improving the image quality and increase the EQE of the pixels.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate of a light emitting structure as shown in the Figures, “down” means toward the substrate, and other directional terms such as top, bottom, above, below, under, beneath, etc. are interpreted accordingly.

FIG. 1 is a sectional diagram of a micro LED panel according to some embodiments (for example, embodiment 1) of the present disclosure.

FIGS. 2˜10 illustrate the steps of a method for manufacturing the micro LED panel in FIG. 1 according to some embodiments (for example, embodiment 1) of the present disclosure.

FIG. 11 is a sectional structure diagram of a micro LED structure according to some embodiments (for example, embodiment 2) of the present invention.

FIGS. 12˜19 illustrate the steps of a method for manufacturing the micro LED structure in FIG. 11 according to some embodiments (for example, embodiment 2) of the present disclosure.

FIG. 20 is a sectional structure diagram of a micro LED structure according to some embodiments (for example, embodiment 3) of the present invention.

FIGs. 21˜27 illustrate the steps of a method for manufacturing the micro LED structure in FIG. 20 according to some embodiments (for example, embodiment 3) of the present disclosure.

FIG. 28 is a sectional structure diagram of a micro LED structure according to some embodiments (for example, embodiment 4) of the present invention.

FIGS. 29˜39 illustrate the steps of a method for manufacturing the micro LED structure in FIG. 28.

FIG. 40 is a sectional structure of another alternative step 6 according to embodiment 4 of the present invention.

FIG. 41 is a sectional structure diagram of another micro LED structure according to some embodiments (for example, an alternative embodiment 4) of the present invention.

FIGS. 42˜50 illustrate the steps of another alternative method for manufacturing the micro LED structure in FIG. 28.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

As discussed above, to resolve the problem in the related technologies, in some embodiments, a micro LED panel comprising multiple micro LED structures is disclosed in the present disclosure. The dimension of the micro LED panel is not more than 1 cm. The micro LED structures are formed in the micro LED panel in an array, with a resolution such as 720*480, 640*480, 1920*1080, 1280*720, 2k, or 4k. The diameter of the micro LED structure is at a nano-meter level, such as 20 nm to 100 nm.

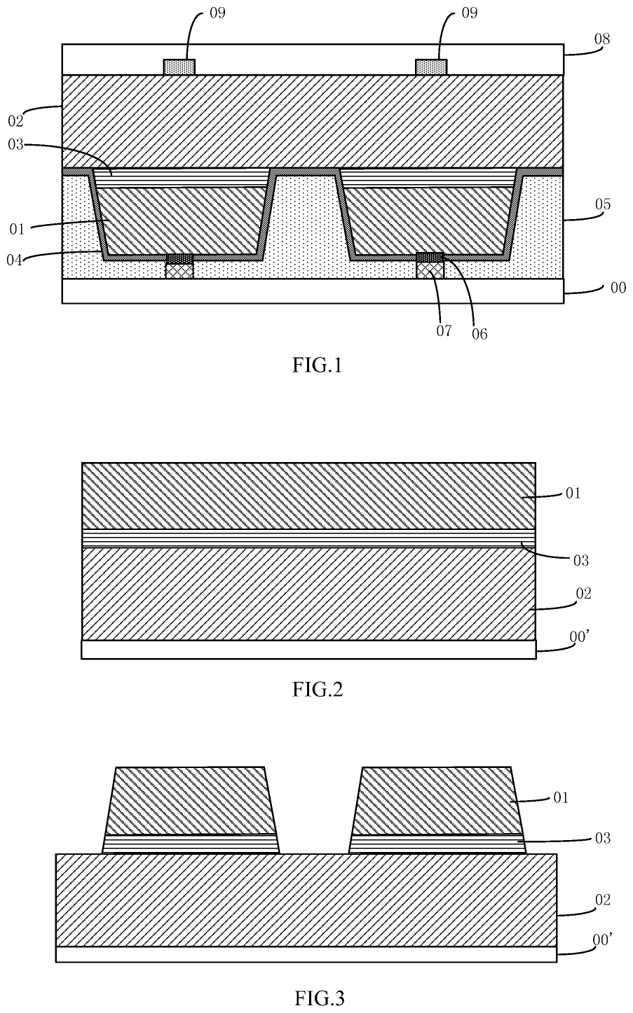

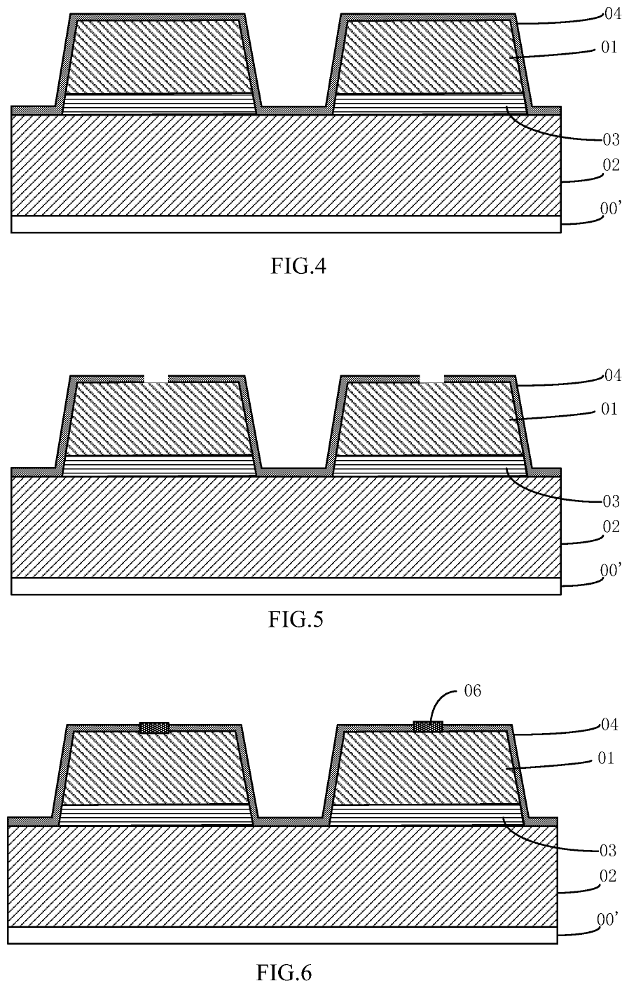

FIG. 1 is a sectional diagram of a micro LED structure according to some embodiments of the present invention. Referring to FIG. 1, the micro LED structure is formed by a first type epitaxial layer 01, a light emitting layer 03 and a second type epitaxial layer 02 from bottom to top. The first type and the second type are different conductive types, for example, the first type is P type, while the second type is N type. In another example, the first type is N type, while the second type is P type. In some embodiments, the material of the first type epitaxial layer 01 can be one or more of p-type GaAs, InGaAs, GaP, GaN, InGaN, AlGaN, AlInP, GaInP, AlGaInP, AlP, InP, AlN, and/or InN, etc., or any combinations thereof, preferably one or more of p-type GaAs, InGaAs, GaP, GaN, InGaN, AlGaN, AlInP, GaInP, and/or AlGaInP, or any combinations thereof, and the material of the second type epitaxial layer 02 can be one or more of n-type GaAs, InGaAs, GaP, GaN, InGaN, AlGaN, AlInP, GaInP, AlGaInP, AlP, InP, AlN, and/or InN, etc., or any combinations thereof, preferably one or more of n-type GaAs, InGaAs, GaP, GaN, InGaN, AlGaN, AlInP, GaInP, and/or AlGaInP, or any combinations thereof.

In some embodiments, the light emitting layer 03 is formed by multiple pairs of quantum well layers. The material of the quantum well layer can be one of GaAs, InGaAs, GaP, GaN, InGaN, AlGaN, AlInP, GaInP, AlGaInP, etc. Additionally, the thickness of the first type epitaxial layer 01 is larger than the thickness of the second type epitaxial layer 02 and the thickness of the light emitting layer 03 is less than that of the first type epitaxial layer 01. Preferably, the thickness of the first type epitaxial layer 01 is 700 nm to 2 μm, the thickness of the second type epitaxial layer 02 is 100 nm to 200 nm. Preferably, the thickness of a single quantum well layer is not more than 30 nm. In some examples, the light emitting layer 03 includes not more than three pairs of quantum well layers.

In some embodiments, the first type epitaxial layer 01 may have multiple stacked first type semiconductor sub-layers, the second type epitaxial layer 02 may have multiple stacked second type semiconductor sub-layers. For example, the top layer of the first type epitaxial sub-layer is a P cap layer connected to the bottom of the light emitting layer 03, the bottom layer of the second type epitaxial sub-layer is an N cap layer connected to the top of the light emitting layer 03, for protecting the quantum well layers from being damaged.

Furthermore, the first type epitaxial layer 01 comprises one or more reflective mirror layers 011 (not shown in FIG. 1). The reflective mirror layer(s) 011 can be formed at the bottom surface of the first type epitaxial layer 01 or formed in the inner of the first type epitaxial layer 01. The material of the reflective mirror layer is a combination of a dielectric material and a metal material. Furthermore, the dielectric material is SiO2 or SiNx, wherein, x is a positive integer; and preferably, the metal material is Au or Ag. In some embodiments, multiple reflective mirror layers 011 are horizontally formed in the first type epitaxial layer 01 one by one in different horizontal levels, thereby dividing the first type epitaxial layer 01 into multiple layers.

In some embodiments, the top contact 09 is formed at the top surface of the second type epitaxial layer 02. The conductive type of the top contact 09 is the same as that of the second type epitaxial layer 02, such as, the second type is n type, the top contact 09 is n type top contact; or, the second type is p type, the top contact 09 is p type top contact. In some embodiments, the top contact 09 is made by metal or metal alloy, such as, AuGe, AuGeNi, etc. The top contact 09 is used for forming ohmic contact between the top conductive layer 08 and the second type epitaxial layer 02, so as to optimize the electrical property of the micro LEDs. The diameter of the top contact 09 is about 20 nm to 50 nm and the thickness of the top contact 09 is about 10 nm to 20 nm. In some embodiments, the top conductive layer 08 is transparent and electrically conductive, such as Indium Tin Oxide (ITO), Fluorine-doped Tin Oxide (FTO), etc.

In some embodiments, the bottom contact 06 is formed at the bottom surface of the first type epitaxial layer 01. The conductive type of the bottom contact 06 is the same as that of the first type epitaxial layer 01, such as, the first type epitaxial layer 01 is P type, the bottom contact 06 is also P type. Furthermore, since the light emits upward or downward from the LED mesa structure consisting or comprising of the first type epitaxial layer 01, and the light emitting layer 03, so the diameter of the bottom contact 06 is larger than the diameter of the top contact 09, while the diameter of the top contact 09 can be as small as possible. Therefore, the top contact 09 is also as a dot on the top surface of the second type epitaxial layer 02. For example, the width of the top contact 09 is less than ⅕, ⅙, 1/10 or 1/20 of the width of the second-type epitaxial layer 02. In some embodiments, the diameter of the bottom contact 06 can also be equal to or smaller than the diameter of the top contact 09. A bottom connected structure 07 is formed at the bottom of the bottom contact 06. The bottom connected structure 07 is used for connecting with the bottom electrode such as the contact pad in an IC backplane. Furthermore, the diameter of the bottom connected structure 07 is 20 nm to 1 μm. Preferably, the diameter of the bottom connected structure 07 is 800 nm to 1 μm. Furthermore, the center of the bottom contact 06 is aligned with the center of the top contact 09 in the vertical direction. In some embodiments, the material of the bottom contact 06 and the bottom connected structure 07 are transparent conductive material, such as ITO, or FTO, etc. Additionally, in some embodiments, the material of the bottom contact 06 and the bottom connected structure 07 are not transparent. The material of the bottom contact 06 and the bottom connected structure 07 can be conductive metal. Preferably, the material of the bottom contact 06 can be selected from at least one of Au, Zn, Be, Cr, Ni, Ti, Ag and Pt. The material of the bottom connected structure 07 can be selected from at least one of Au, Zn, Be, Cr, Ni, Ti, Ag and Pt.

As shown in FIG. 1, In some embodiments the center of the bottom contact 06 is vertically aligned with the center of the first type epitaxial layer 01. But, in another embodiment, the center of the bottom contact 06 is not vertically aligned with the center of the first type epitaxial layer 01.

In some embodiments, to avoid the surface carrier loss and the non-radiative recombination at the sidewall of the mesa structure, a re-growth layer 04 by a re-growth process is formed on the sidewall of the light emitting layer 03, even on the sidewall of the first type epitaxial layer 01 and on the sidewall of the second type epitaxial layer 02. For example, the re-growth layer can be grown on part of the sidewall of the light emitting layer 03 or on the whole sidewall of the light emitting layer. “Whole” means a substantial or entire portion. Furthermore, the re-growth layer 04 can be further formed on part of the first type epitaxial layer 01 or the whole sidewall of the first type epitaxial layer 01; and/or, the re-growth layer 04 can be further formed on part of the second type epitaxial layer 02 or the whole sidewall of the second type epitaxial layer 02.

The re-growth layer 04 on the sidewall of the light emitting layer 03 is not parallel to the extending horizontal direction of the light emitting layer 03 as shown in FIG. 1. Furthermore, the light emitting layer 03 comprises a top surface, an edge surface and a bottom surface; and, the re-growth layer 04 is only grown on the edge surface of the light emitting layer 03 but not grown on the top surface and the bottom surface of the light emitting layer 03. Preferably, the inclined angle of the re-growth layer 04 on the sidewall of the light emitting layer is 30° to 90° relative to the horizontal direction of the light emitting layer 03. That is to say, the re-growth layer 04 is grown on the end surface of the light emitting layer 03, but not grown on the top and bottom of the light emitting layer 03. Additionally, the light emitting layer 03 comprises a plurality of pairs of quantum wells. The re-growth layer 04 is not parallel to the surface of each of the plurality of pairs of quantum wells. Herein, the light emitting layer 03 is has a straight-line shape without any bending. Preferably, the diameter of the mesa structure is not more than 3 μm.

Herein, the material of the re-growth layer 04 with intrinsic doped ions is the same as the material of the first type epitaxial layer 01 and/or the material of the second type epitaxial layer 02 but without intentional extrinsic doping ions. For example, when the materials of first type epitaxial layer 01 and the second type epitaxial layer 02 are the same, and the intentional ion doping levels for the material of first type epitaxial layer 01 and the material of the second type epitaxial layer 02 are different, the material of the re-growth layer 04 may be the same as the underlying first type epitaxial layer 01 and the material of the second type epitaxial layer 02 but without the intentional extrinsic doping ions. In another example, when the material of first type epitaxial layer 01 and the second type epitaxial layer 02 are not the same, and the intentional ion doping levels for the material of first type epitaxial layer 01 and the material of the second type epitaxial layer 02 are different, the material of the re-growth layer 04 may be the same as the first type epitaxial layer 01 or the material of the second type epitaxial layer 02 but without the intentional extrinsic doping ions. The light emitting layer is an active region of a PN-junction formed by the first type epitaxial layer 01 and the second type epitaxial layer 02, and can be considered as composed of the two materials of the first type epitaxial layer 01 and the second type epitaxial layer 02. In some embodiments, the portion of the material of the re-growth layer that covers the first type epitaxial layer 01 is the same as the underlying first type epitaxial layer 01 but without the extrinsic intentional doping of the first type epitaxial layer 01, and the portion of the material of the re-growth layer that covers the second type epitaxial layer 02 is the same as the underlying second type epitaxial layer 02 but without the extrinsic intentional doping of the second type epitaxial layer 02. In some embodiments, the re-growth layer 04 can have some intrinsic doping levels or without doping levels. In some embodiments, the material growth parameters, such as the ambient/gas pressure, the power, and the material for the re-growth process are the same or similar as that of the first type epitaxial layer 01 and/or second type epitaxial layer 02. The material of the re-growth layer 04 must be lattice matched with the light emitting layer 03, the first type epitaxial layer 01 and/or the second type epitaxial layer 02. Preferably, the material of the re-growth layer 04 is monocrystal, the material of the first epitaxial layer 01 is monocrystal and the material of the second epitaxial layer 02 is monocrystal. Furthermore, the material of the re-growth layer 04 is selected from one or more of GaAs, InGaAs, GaP, GaN, InGaN, AlGaN, AlInP, GaInP, AlGaInP, AlP, InP, AlN, and/or InN, etc., or any combinations thereof, preferably one or more of GaP, AlP, GaAs, InP, AlInP, GaInP, AlN, GaN, and/or InN, or any combinations thereof. In another embodiment, the material of the re-growth layer 04 is without intentional doping ions and is not the same as the material of the first type epitaxial layer or the material of the second type epitaxial layer 02.

The resistance of the re-growth layer 04 is higher than the resistance of the light emitting layer 03 and the re-growth layer 04 is not electrically conductive, thereby ensuring the normal work of the micro LED structures, and stopping the carries spreading outside the light emitting layer 03. Preferably, the band gap of the re-growth layer 04 is greater than the band gap of the light emitting layer 03. Furthermore, the thickness of the re-growth layer 04 is less than the thickness of the light emitting layer 03, preferably, the thickness of the re-growth layer 04 is not more than 10 nm or 100 nm. In another embodiments, the thickness of the re-growth layer 04 is equal to or more than the thickness of the light-emitting layer 03.

Hereinafter, the detail of the micro LED panel and the method of manufacturing the micro LED panel will be described in consistent with the figures.

### Embodiment 1

To resolve the problem in the related technologies, a micro LED panel is provided in the embodiments of the present invention.

The micro LED panel comprises a micro LED structure array. Referring to FIG. 1, the micro LED structures in the micro LED panel comprises: a mesa structure comprising 01, and 03, a re-growth layer 04, a top contact 09, a top conductive layer 08, a bottom contact 06, a bottom connected structure 07, an IC backplane 00 and a dielectric layer 05 between the adjacent mesa structures.

The mesa structure herein comprises a first type epitaxial layer 01 and a light emitting layer 03 from bottom to up, but not comprises the second type epitaxial layer 02. The second type epitaxial layer 02 is continuously formed on the top of the whole micro LED panel. Furthermore, the second type epitaxial layer 02 is continuously formed on the top of the light emitting layer 03 and the top of the re-growth layer 04.

The re-growth layer 04 is grown on the whole sidewall of the light emitting layer 03 and on the whole sidewall of the first type epitaxial layer 01. Furthermore, the re-growth layer 04 is further formed on the bottom surface of the first type epitaxial layer 01. In some embodimentsIn some embodiments, the re-growth layer 04 is grown on part of the first type epitaxial layer 01 and not formed at the bottom surface of the first type semiconductor layer 01. Furthermore, the re-growth layer 04 is very thin not more than 10 nm, such as 5 nm, so the re-growth layer 04 is transparent in some embodiments.

A dielectric layer 05 is formed between the adjacent mesa structures. Preferably, the material of the dielectric layer 05 is one or more of SiO₂, SiNx, Al₂O₃, AlN, HfO₂, TiO₂, and/or ZrO₂, etc. Additionally, the material of the dielectric layer 05 is transparent in some embodiments. The top end of the re-growth layer 04 further extrudes along the top surface of the dielectric layer 05. The second type epitaxial layer 02 is formed on the top of the light emitting layer 03 and the top of the re-growth layer 04. The part of the re-growth layer 04 which is extruded along and on the top of the dielectric layer 05 is parallel to the top surface of the dielectric layer 05. Furthermore, the re-growth layer 04 extruded along the top of the dielectric layer 05 is connected to the adjacent light emitting layer 03 and the first type epitaxial layer 01. Additionally, the bottom contact 06 and the bottom connected structure 07 is formed in the dielectric layer 05 at the bottom of the first type epitaxial layer 01. The top contact 09 and the top conductive layer 08 are formed on the top of the second type epitaxial layer 02. In some embodiments, the top conductive layer 08 is continuously formed on the whole micro LED panel in the embodiment. In another embodiment, the top conductive layer 08 is formed on the top contact and part of the top surface of the second type epitaxial layer 02.

In some embodiments, the method of manufacturing the aforementioned micro LED panel in this embodiment 1 comprises the following steps.

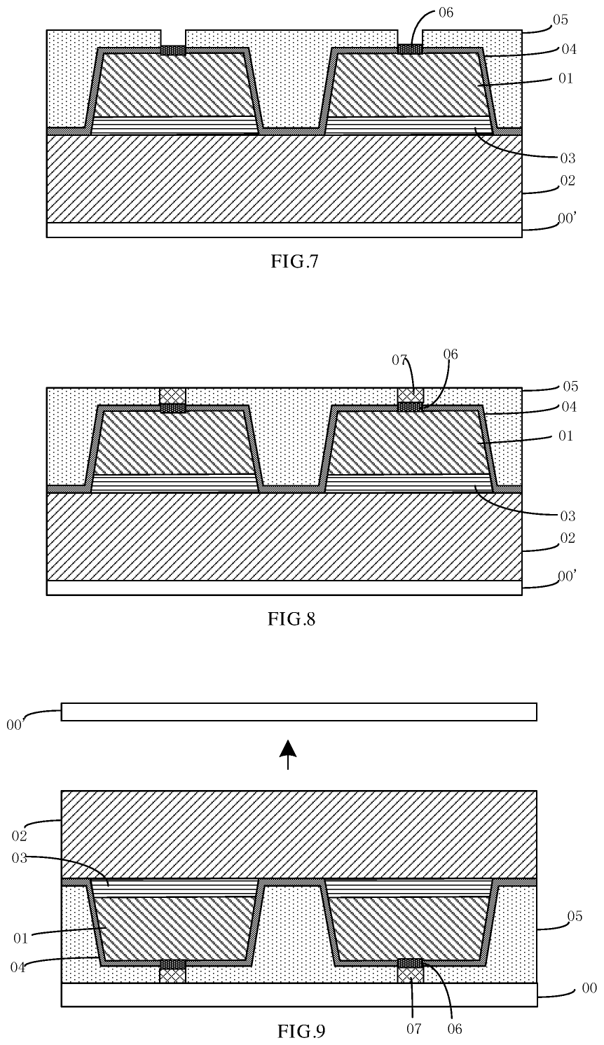

FIGS. 2-15 illustrate the steps of a method for manufacturing the micro LED structure in FIG. 1 according to some embodiments (for example, embodiment 1) of the present disclosure.

Referring to FIG. 2, step 1 includes supplying a semiconductor substrate 00′ with an epitaxial structure; and, the epitaxial structure includes a first type epitaxial layer 01, a light emitting layer 03 and a second type epitaxial layer 02 from top down.

Herein, the epitaxial structure includes a first type epitaxial layer 01, a light emitting layer 03 and a second type epitaxial layer 02 from top down. The material of the semiconductor substrate 00′ can be GaN, GaAs, etc. The epitaxial structure is grown on the substrate 00′.

Referring to FIG. 3, step 2 includes forming a mesa structure by patterning the first type epitaxial layer 01 and the light emitting layer 03.

Herein, the first type epitaxial layer 01 and the light emitting layer 03 are etched from top down by a conventional plasma etching process.

Referring to FIG. 4, step 3 includes forming a re-growth layer 04 on the sidewall of the light emitting layer 03 and on at least part of the sidewall of the first type epitaxial layer 01 by an epitaxial material re-growth process.

Herein, the re-growth layer 04 is grown on the sidewall of the light emitting layer 03, on the sidewall and the top of the first type epitaxial layer 01, and on the top surface of the second type epitaxial layer 02 in FIG. 4. In this re-growth process, the temperature is 400° C. to 1000° C., and the re-growth time is 5 seconds to 1000 seconds. In some embodiments, the material for re-growth process is the same as the material of the first type epitaxial layer and/or the material of the second type epitaxial layer but without intentional extrinsic doping ions.

In another embodiment, a mask covers the top and part of the sidewall of the first type epitaxial layer 01. Therefore, the re-growth layer 04 is formed on the whole sidewall of the light emitting layer 03 and part of the sidewall of the first type semiconductor layer 01.

In some embodiments, in the etching process of step 2, when the second type epitaxial layer 02 is etched a certain depth, the re-growth layer 04 may be further formed on part of the sidewall of the second type epitaxial layer 02. Therefore, the position of the re-growth layer 04 is decided by the etch depth in this step 2.

Referring to FIGS. 5-7, step 4 includes forming a dielectric layer 05 on the re-growth layer 04 and forming an opening in the dielectric layer 05 on the first type epitaxial layer 01; and, forming a bottom contact 06 in the opening on the surface of the first type epitaxial layer 01.

Herein, firstly, referring to FIG. 5, a first opening is formed in the re-growth layer 04 on the top of the mesa structure. Then, referring to FIG. 6, the bottom contact 06 is deposited in the first opening on the first type epitaxial layer 01; next, referring to FIG. 7, the dielectric layer 05 is formed on the surface of the re-growth layer 04 and the top of the bottom contact 06; finally, a second opening is formed in the dielectric layer 05 on the first opening, exposing the bottom contact 06.

In some embodiments, the bottom contact 06 can be formed on the top of the mesa structure before forming the re-growth layer 04. Any other steps for forming the dielectric layer 05, forming the bottom contact 06 in the opening can be used in the present method and will be in the scope of the present disclosure.

Referring to FIG. 8, step 5 includes forming a bottom connected structure 07 in the opening.

Herein, the material of the bottom connected structure 07 is deposited into the opening and on the bottom contact 06 by a conventional vapor deposition process.

Referring to FIG. 9, step 6 includes bonding the first type epitaxial layer 01 and the bottom connected structure 07 with an IC backplane 00 by turning the semiconductor substrate 00′ upside down; then, removing the semiconductor substrate 00′.

Herein, the semiconductor substrate 00′ with the epitaxial structure is firstly turned upside down. Then, the bottom connected structure 07 is bonded with a pad of the IC backplane 00. After the bonding process, the semiconductor substrate 00′ is removed by a conventional removing process, such as laser lift-off method.

Referring to FIG. 10, step 7 includes forming a top contact 09 and a top conductive layer 08 on the second epitaxial layer 02.

Herein, the top contact 09 is deposited on the top of the second type epitaxial layer 02 with a mask protecting the other region. Then, a top conductive layer 08 is deposited on the second epitaxial layer 02 by a conventional vapor deposition process.

### Embodiment 2

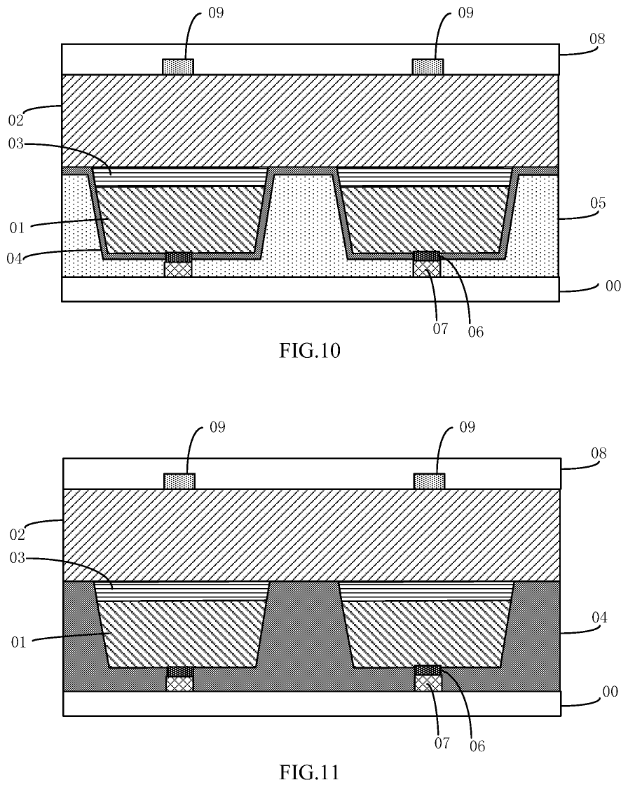

The micro LED panel of embodiment 2 comprises a micro LED structure array. FIG. 11 is a sectional structure diagram of a micro LED structure according to some embodiments (for example, embodiment 2) of the present invention. Referring to FIG. 11, the micro LED structure comprises: a mesa structure, a continuous second type epitaxial layer 02, a re-growth layer 04, a bottom contact 06, a bottom connected structure 07, an IC backplane 00, a top contact 09 and a top conductive layer 08.

The mesa structure in this embodiment comprises the first type epitaxial layer 00, the light emitting layer 03 from down to top, but not comprises the second type epitaxial layer 02. The second type epitaxial layer 02 is continuously formed on the top of the whole micro LED panel. Furthermore, the second type epitaxial layer 02 is continuously formed on the top of the light emitting layer 03 and the top of the re-growth layer 04.

The re-growth layer 04 is grown on the whole sidewall of the first type epitaxial layer 01 and the whole sidewall of the light emitting layer 03 and fully filled between the adjacent mesa structure. That is to say, the re-growth layer 04 is fully filled in the space between the adjacent mesa structures. Preferably, the top of the re-growth layer 04 is aligned with the top of the light emitting layer 03. The bottom of the re-growth layer 04 is lower than the bottom of the light emitting layer 03. In some embodiments, the bottom of the re-growth layer 04 is lower than the bottom of the mesa structure. Furthermore, the top width of the re-growth layer 04 is the same as the top width of the space width between the adjacent light emitting layers 03. Furthermore, the re-growth layer 04 is very thin not more than 10 nm, such as 5 nm, so the re-growth layer 04 is transparent in some embodiments.

Herein, the re-growth layer 04 is formed between the adjacent micro LED structures without any dielectric layer formed therein. The bottom contact 06 and the bottom connected structure 07 is formed in the re-growth layer 04 below and electrically connected to the first type epitaxial layer 01. Additionally, the top contact 09 and the top conductive layer 08 are formed on the top of the second type epitaxial layer 02. In some embodiments, the top conductive layer 08 is continuously formed on the whole micro LED panel. In another embodiment, the top conductive layer 08 is formed on the top contact 09 and part of the top surface of the second type epitaxial layer 02.

The method of manufacturing the aforementioned micro LED panel in this embodiment 2 comprises the following steps.

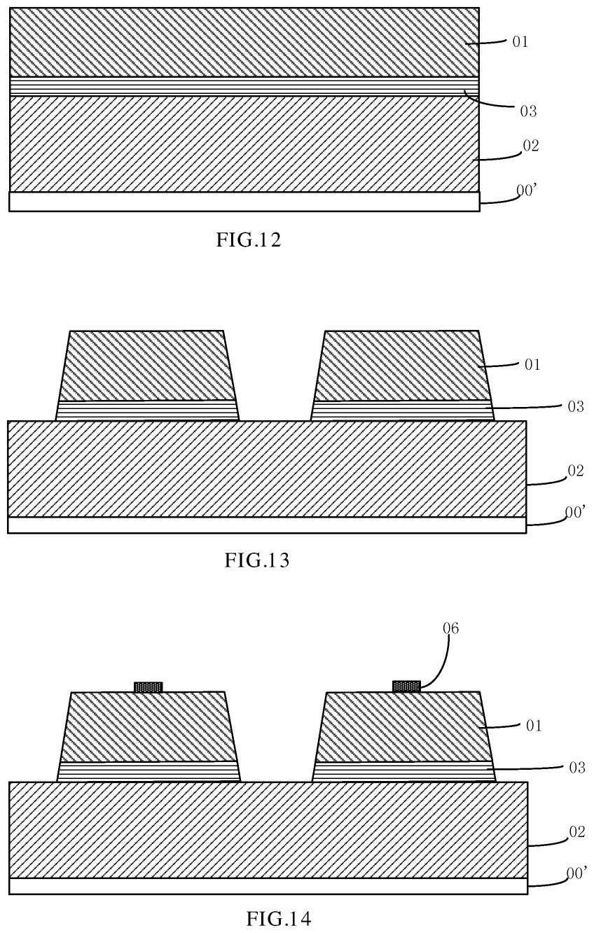

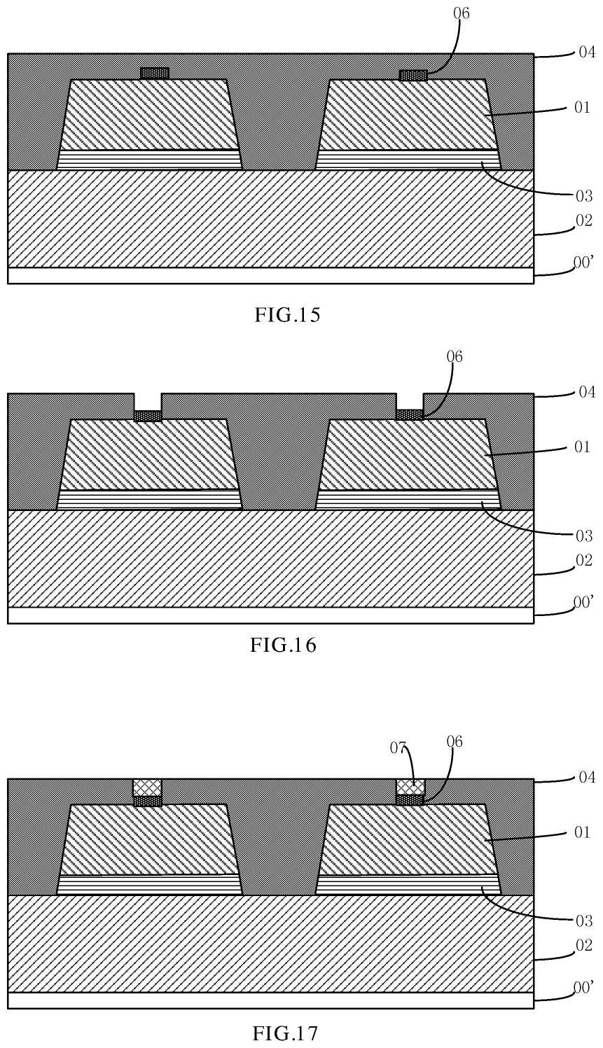

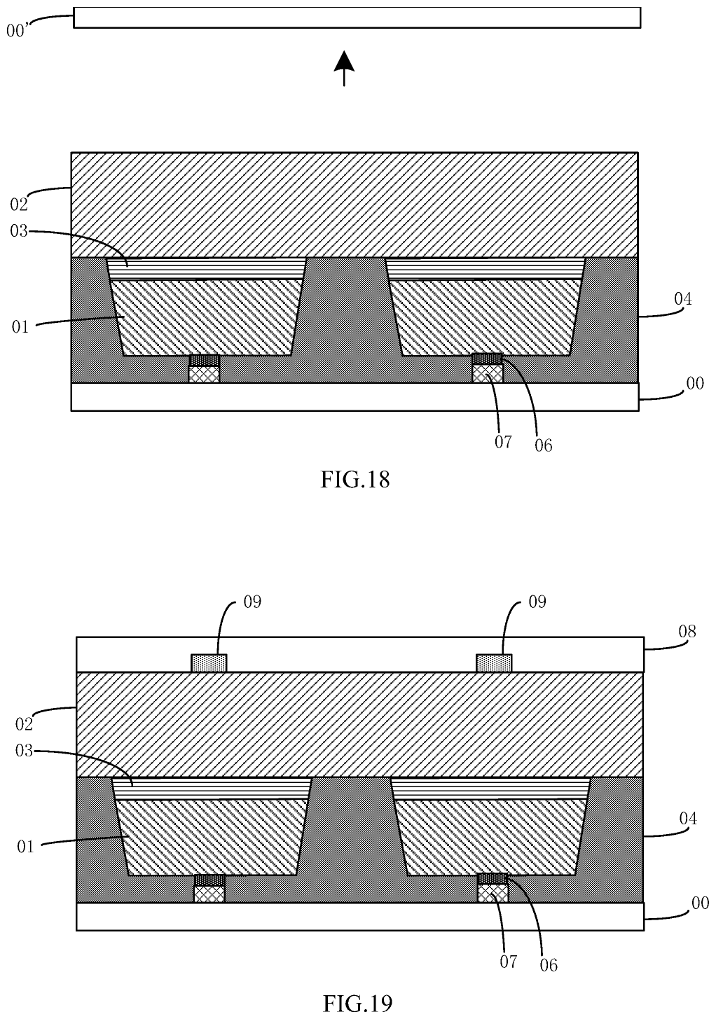

FIGS. 12˜19 illustrate the steps of a method for manufacturing the micro LED structure in FIG. 11 according to some embodiments (for example, embodiment 2) of the present disclosure.

Referring to FIG. 12, step 1 includes supplying a semiconductor substrate 00 with an epitaxial structure. The epitaxial structure comprises a first type epitaxial layer 01, a light emitting layer 03 and a second type epitaxial layer 02 from top down

Herein, the epitaxial structure comprises a first type epitaxial layer 01, a light emitting layer 02 and a second type epitaxial layer 03 from top down. The material of the semiconductor substrate 00′ can be GaN, GaAs, etc., on which the epitaxial structure is grown.

Referring to FIG. 13, step 2 includes forming a mesa structure by patterning the first type epitaxial layer 01 with the light emitting layer 03, and forming a bottom contact 06 on the top of the mesa structure.

Herein, the first type epitaxial layer 01 with the light emitting layer 03 are etched from top down by a conventional plasma etching process. The bottom contact 06 is deposited on the top of the first type epitaxial layer 01 by a conventional vapor deposition method with a mask covering another region.

Then, referring to FIG. 14, forming a bottom contact 06 on the top surface of the first type epitaxial layer 01.

In another embodiment, in the etching process of step 2, when the second type epitaxial layer 02 is etched a certain depth, the re-growth layer 04 may be further formed on part of the sidewall of the second type epitaxial layer. Therefore, the position of the re-growth layer 04 is decided by the etch depth in this step 2.

Referring to FIG. 15, step 3 includes forming a re-growth layer 04 fully filled in the space of the adjacent mesa structures and on the whole sidewall of the light emitting layer 03 and on the whole sidewall of the first type epitaxial layer 01 by an epitaxial material re-growth process.

Herein, the re-growth layer 04 is grown on the sidewall of the light emitting layer 03, the sidewall and the top of the first type semiconductor layer 01 and on the top surface of the second type epitaxial layer 02. In this re-growth process, the temperature is 400° C. to 1000° C., and the re-growth time is 5 seconds to 1000 seconds. The material for re-growth process is the same as the material of the first type epitaxial layer and/or the material of the second type epitaxial layer but without intentional extrinsic doping ions.

Referring to FIG. 16, step 4 includes forming an opening in the re-growth layer 04 on the first type epitaxial layer 01.

Herein, the opening is formed in the re-growth layer 04 by a conventional plasma etching process.

Referring to FIG. 17, step 5 includes forming a bottom connected structure 07 in the opening.

Herein, before forming the bottom connected structure 07, a bottom contact 06 is formed in the opening on the first type epitaxial layer 01. The material of the bottom connected structure 07 is deposited into the opening and on the bottom contact 06 by a conventional vapor deposition process.

Referring to FIG. 18, step 6 includes bonding the bottom connected structure 07 with an IC backplane 00 by turning the semiconductor substrate 00′ upside down, then, removing the semiconductor substrate 00′.

Herein, the semiconductor substrate 00′ with the epitaxial structure is firstly turnedturned upside down. Then, the bottom connected structure 07 is bonded with a pad of the IC backplane 00. After the bonding process, the semiconductor substrate 00′ is removed by a conventional removing process, such as a laser lift-off method.

Referring to FIG. 19, step 7 includes forming a top contact 09 and a top conductive layer 08 on the second epitaxial layer 02.

Herein, the top contact 09 is deposited on the top of the second type epitaxial layer 02 with a mask protecting the other region. Then, a top conductive layer 08 is deposited on the second epitaxial layer 02 by a conventional vapor deposition process.

### Embodiment 3

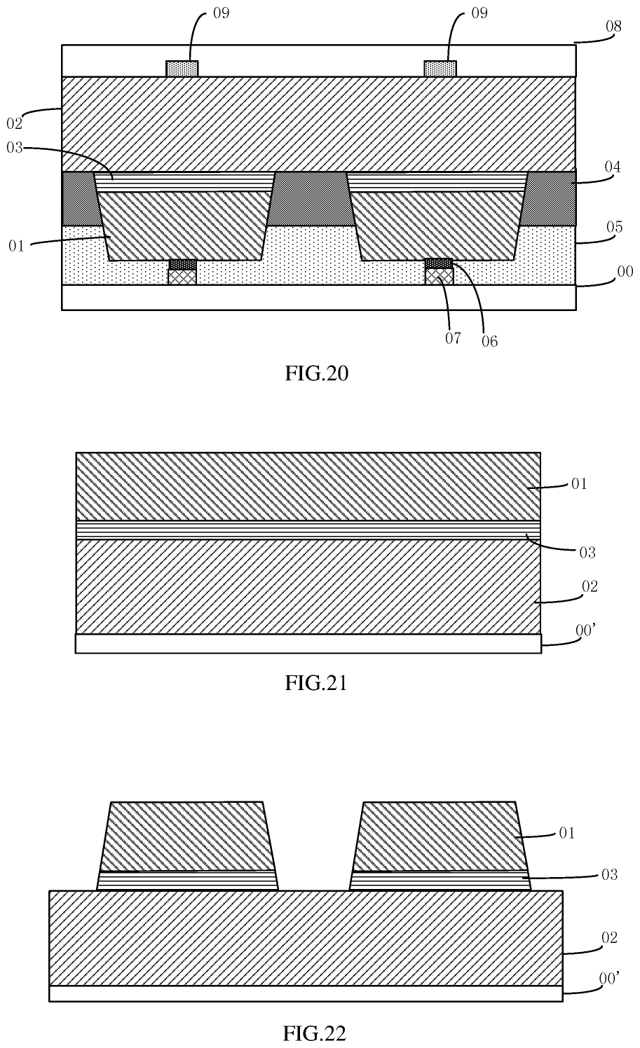

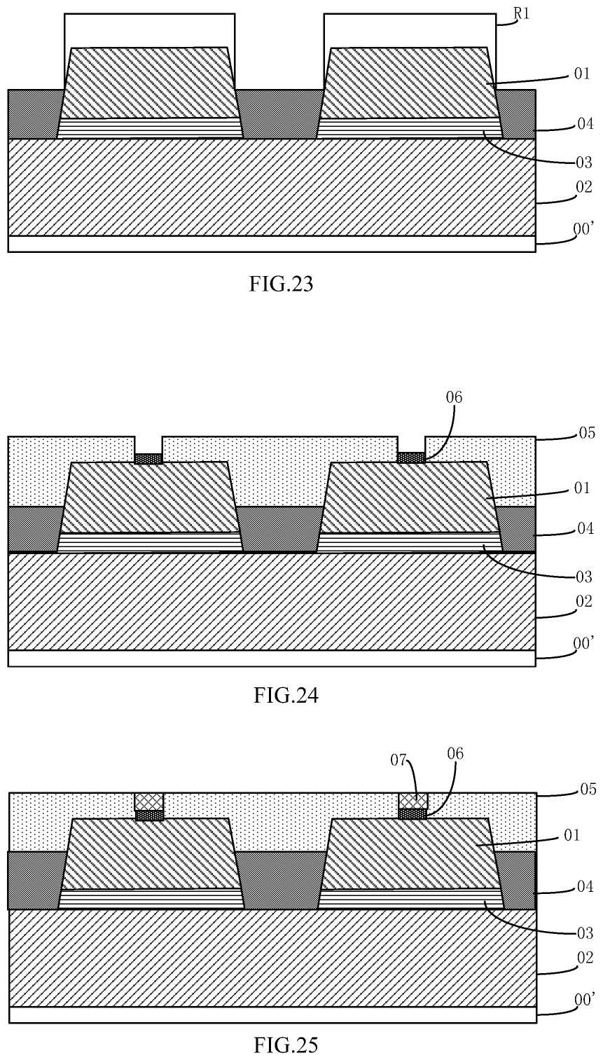

The micro LED panel of embodiment 3 comprises a micro LED structure array. FIG. 20 is a sectional structure diagram of a micro LED structure according to some embodiments (for example, embodiment 3) of the present invention.

Referring to FIG. 20, the micro LED structure comprises: a mesa structure, a continuous second type epitaxial layer 02, a re-growth layer 04, a bottom contact 06, a bottom connected structure 07, an IC backplane 00, a top contact 09 and a top conductive layer 08.

The mesa structure in this embodiment consists of or comprises the first type epitaxial layer 01, the light emitting layer 03 from bottom to top, but does not comprise the second type epitaxial layer 02. The second type epitaxial layer 02 is continuously formed on the top of the whole micro LED panel. Furthermore, the second type epitaxial layer 02 is continuously formed on the top of the light emitting layer 03 and the top of the re-growth layer 04.

In some embodiments, the re-growth layer 04 is grown on the whole sidewall of the light emitting layer 03 and on part of the sidewall of the first type epitaxial layer 01. Furthermore, the re-growth layer 04 is fully filled between the adjacent light emitting layers 03. That is to say, the re-growth layer 04 is fully filled in the space between the adjacent light emitting layers 03. Preferably, the top of the re-growth layer 04 is aligned with the top of the light emitting layer 03, the bottom of the re-growth layer 04 is lower than the bottom of the light emitting layer 03. Furthermore, the top width of the re-growth layer 04 is the same as the top space width between the adjacent light emitting layers 03. Furthermore, the re-growth layer 04 is very thin not more than 10 nm, such as 5 nm, so the re-growth layer 04 is transparent in some embodiments.

In some embodiments, a dielectric layer 05 is formed at the bottom of the re-growth layer 04 between the adjacent mesa structures. The dielectric layer 05 is further formed at the bottom of the mesa structure. The bottom contact 06 and the bottom connected structure 07 are formed in the dielectric layer 05 at the bottom of the mesa structure and electrically connected to the first type epitaxial layer 01. Additionally, the material of the dielectric layer 05 is transparent in some embodiments. Preferably, the material of the dielectric layer 05 is one or more of SiO₂, SiNx, Al₂O₃, AlN, HfO₂, TiO₂, and/or ZrO₂, etc.

Additionally, the top contact 09 and the top conductive layer 08 are formed on the top of the second type epitaxial layer 02. In some embodiments, the top conductive layer 08 is continuously formed on the whole micro LED panel. In another embodiment, the top conductive layer 08 is formed on the top contact 09 and part of the top surface of the second type epitaxial layer 02.

Referring to FIG. 20, the method of manufacturing the aforementioned micro LED panel in this embodiment 3 comprises the following steps.

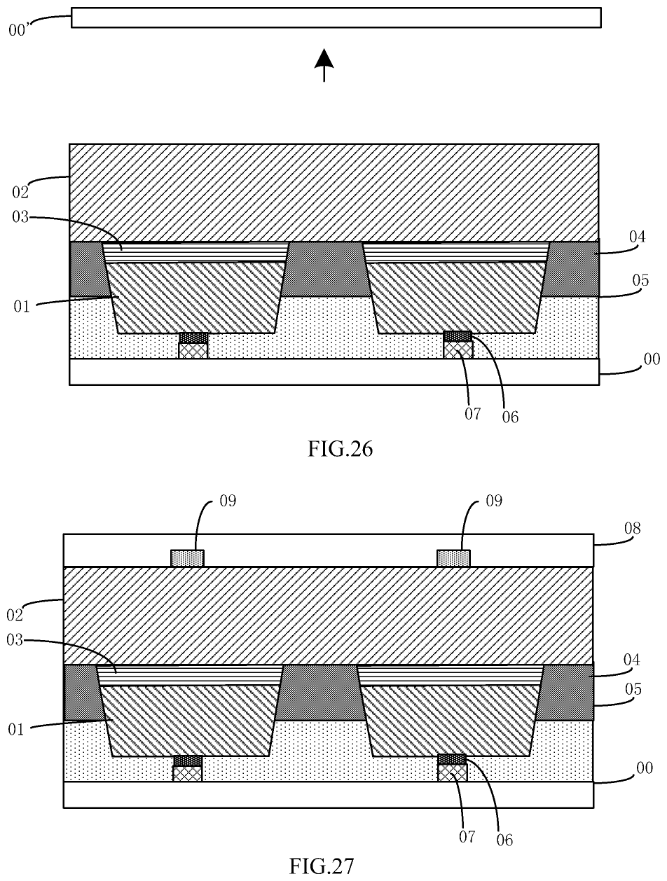

FIGS. 21˜27 illustrate the steps of a method for manufacturing the micro LED structure in FIG. 20 according to some embodiments (for example, embodiment 3) of the present disclosure.

Referring to FIG. 21, step 1 includes supplying a semiconductor substrate 00′ with an epitaxial structure; and the epitaxial structure includes a first type epitaxial layer 01, a light emitting layer 03 and a second type epitaxial layer 02 from top down.

Herein, the epitaxial structure comprises a first type epitaxial layer 01, a light emitting layer 03 and a second type epitaxial layer 02 from top down. The material of the semiconductor substrate 00′ can be GaN, GaAs, etc., on which the epitaxial structure is grown.

Referring to FIG. 22, step 2 includes forming a mesa structure by patterning the first type epitaxial layer 01 and the light emitting layer 03.

Herein, the first type epitaxial layer 01 and the light emitting layer 03 are etched from top down by a conventional plasma etching process.

Referring to FIG. 23, step 3 includes forming a re-growth layer 04 on the whole sidewall of the light emitting layer 03 and on part of the sidewall of the first type epitaxial layer 01 by an epitaxial material re-growth process.

Herein, the re-growth layer 04 is grown on the sidewall of the light emitting layer 03, the whole sidewall and the top of the first type semiconductor layer 01 and on the top surface of the second type epitaxial layer 02 with a mask R1 covering the top and part of the sidewall of the first type epitaxial layer 01. In this re-growth process, the temperature is 400° C. to 1000° C., and the re-growth time is 5 seconds to 1000 seconds. The material for re-growth process is the same as the material of the first type epitaxial layer and/or the material of the second type epitaxial layer but without intentional extrinsic doping ions.

In some embodiments, in the etching process of step 2, when the second type epitaxial layer 02 is etched a certain depth, the re-growth layer 04 may be further formed on part of the sidewall of the second type epitaxial layer 02. Therefore, the position of the re-growth layer 04 is decided by the etch depth in this step 2.

Referring to FIG. 24, step 4 includes forming a dielectric layer 05 on the re-growth layer 04 and forming an opening in the dielectric layer 05 on the first type epitaxial layer 01, and forming a bottom contact 06 in the opening on the surface of the first type epitaxial layer 01.

Herein, a dielectric layer 05 is firstly deposited on the re-growth layer 04, on the sidewall and the top of the first type epitaxial layer 01. Then, an opening is formed in the dielectric layer 05 on the first type epitaxial layer 01. Next, the bottom contact 06 is formed in the opening and connected to the first type epitaxial layer 01.

In some embodiments, the step 4 comprises the following steps. firstly, an initial dielectric layer is deposited on the re-growth layer, on the sidewall and the top of the first type epitaxial layer. Then, the top of the initial dielectric layer is planarized to the top of the first type epitaxial layer; and, the bottom contact is deposited on the first type epitaxial layer. Then, another dielectric layer is deposited on the initial dielectric layer and the sidewall and the top of the mesa structure, and covers the top contact, to form the completed dielectric layer. Next, an opening is formed in the dielectric layer and exposing the bottom contact.

Referring to FIG. 25, step 5 includes forming a bottom connected structure 07 in the opening.

Herein, the material of the bottom connected structure 07 is deposited into the opening and on the bottom contact by a conventional vapor deposition process.

Referring to FIG. 26, step 6 includes bonding the bottom connected structure 07 with an IC backplane 00 by turning the semiconductor substrate 00′ upside down, then, removing the semiconductor substrate 00′.

Herein, the semiconductor substrate 00′ with the epitaxial structure is firstly turnedturned upside down. Then, the bottom connected structure 07 is bonded with a pad of the IC backplane 00. After the bonding process, the semiconductor substrate 00′ is removed by a conventional removing process, such as a laser lift-off method.

Referring to FIG. 27, step 7 includes forming a top contact 09 and a top conductive layer 08 on the second epitaxial layer.

Herein, the top contact 09 is deposited on the top of the second type epitaxial layer 02 with a mask protecting the other region. Then, a top conductive layer 08 is deposited on the second epitaxial layer 02 by a conventional vapor deposition process.

### Embodiment 4

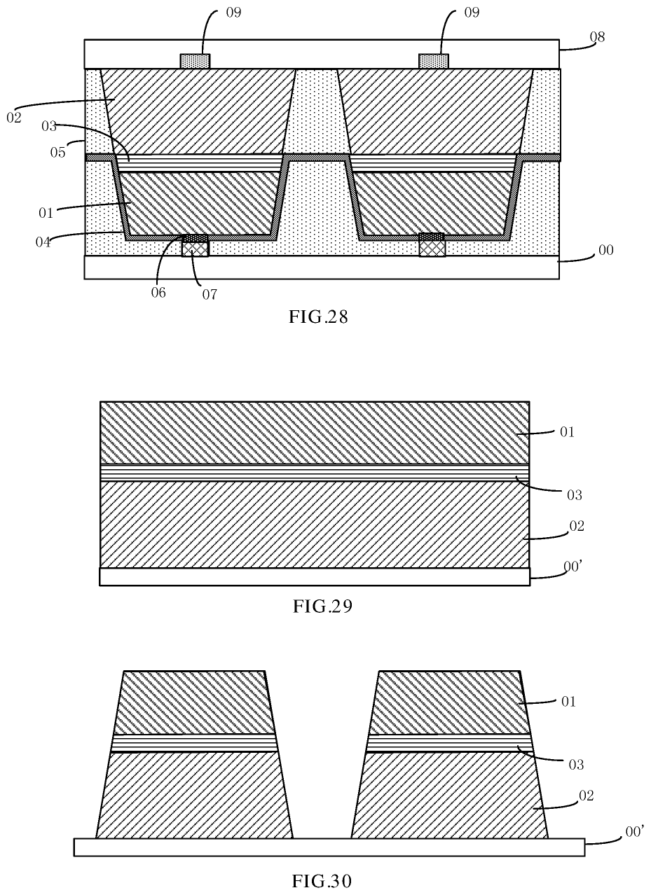

The micro LED panel of embodiment 4 comprises a micro LED structure array. FIG. 28 is a sectional structure diagram of a micro LED structure according to some embodiments (for example, embodiment 4) of the present invention.

Referring to FIG. 28, the micro LED structure in the micro LED panel comprises: a mesa structure, a re-growth layer 04, a bottom contact 06, a bottom connected structure 07, an IC backplane 00, a top contact 09 and a top conductive layer 08. A dielectric layer 05 is formed between the adjacent mesa structures.

The mesa structure from bottom to top consists of or comprises: a first type epitaxial layer 01, a light emitting layer 03 and a second type epitaxial layer 02. The re-growth layer 04 is grown on the sidewall of the first type epitaxial layer 01 and on the whole sidewall of the light emitting layer 03. In some embodiments, the re-growth layer 04 is grown on part of the sidewall of the first type epitaxial layer 01 and on the whole sidewall of the light emitting layer 03. Furthermore, the re-growth layer 04 is very thin such as 5 nm, so the re-growth layer 04 is transparent in some embodiments.

In some embodiments, a dielectric layer 05 is formed between the adjacent mesa structures. Furthermore, the dielectric layer 05 is formed on the surface of the re-growth layer 04 between the adjacent mesa structures. The top end of the re-growth layer 04 further extrudes into the dielectric layer 05. Preferably, the top end of the re-growth layer 04 is connected to the adjacent light emitting layer 03 and the adjacent first type epitaxial layer 01. Additionally, the top end of the re-growth layer 04 extruded into the dielectric layer is parallel to the bottom surface of the second type epitaxial layer 02. Preferably, the material of the dielectric layer 05 is one or more of SiO₂, SiNx, Al₂O₃, AlN, HfO₂, TiO₂, and/or ZrO₂, etc. Additionally, the material of the dielectric layer 05 is transparent in some embodiments.

Herein, the top of the re-growth layer 04 is aligned with the top of the light emitting layer 03, and, the bottom of the re-growth layer 04 is aligned with the bottom of the first type epitaxial layer 01; and, further, the re-growth layer 04 is formed at the bottom of the first type epitaxial layer 01. The bottom contact 06 is formed at the bottom of the first type epitaxial layer 01 in the re-growth layer 04; and, the bottom connected structure 07 is formed at the bottom of the bottom contact 06 in the dielectric layer 05.

Additionally, the top contact 09 and the top conductive layer 08 are formed on the top of the second type epitaxial layer 02. In some embodiments, the top conductive layer 08 is continuously formed on the whole micro LED panel. In another embodiment, the top conductive layer 08 is formed on the top contact and part of the top surface of the second type epitaxial layer 02.

The method of manufacturing the aforementioned micro LED panel in this embodiment 4 comprises the following steps.

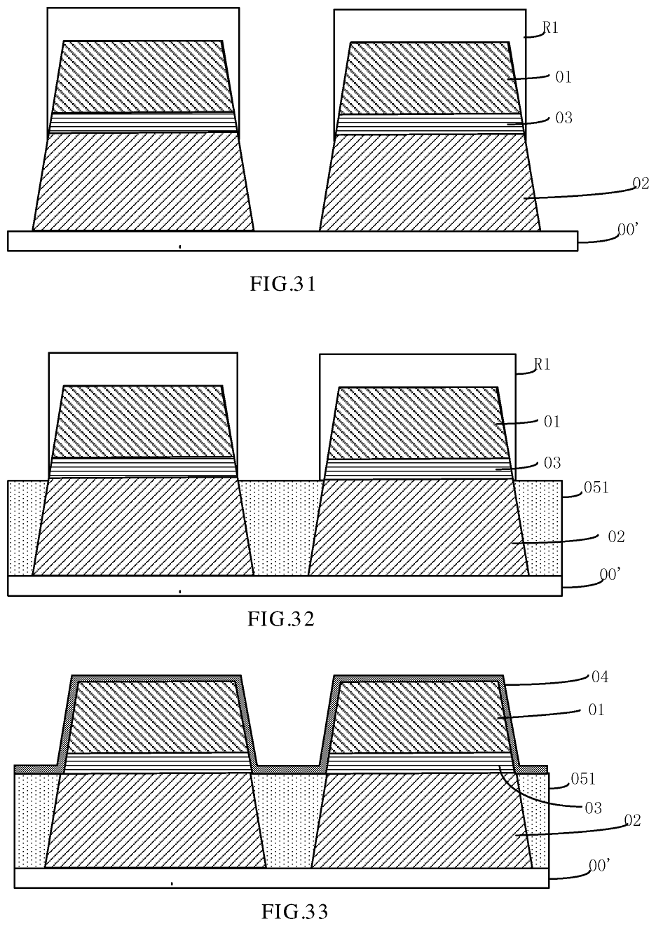

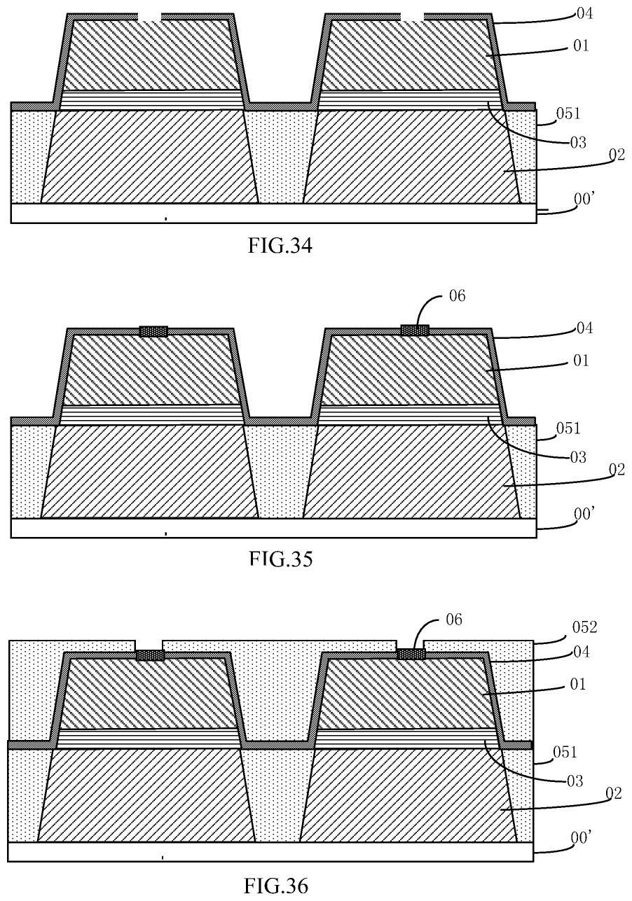

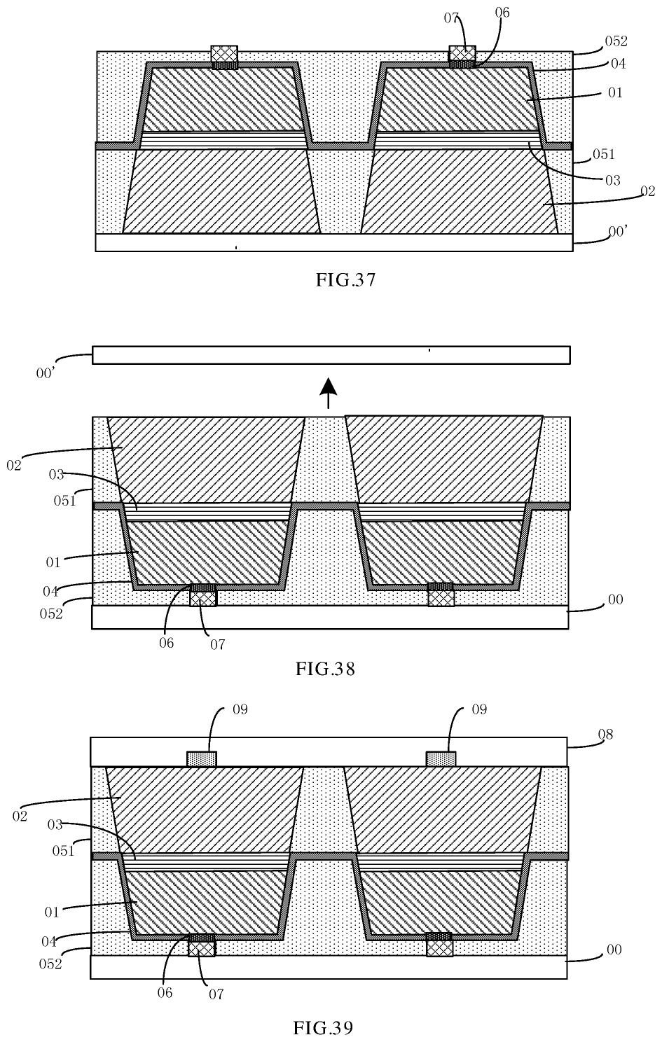

FIGS. 29˜39 illustrate the steps of a method for manufacturing the micro LED structure in FIG. 28.

Referring to FIG. 29, step 1 includes supplying a semiconductor substrate 00′ with an epitaxial structure.

Herein, the epitaxial structure comprises a first type epitaxial layer 01, a light emitting layer 03 and a second type epitaxial layer 02 from top down. The material of the semiconductor substrate 00′ can be GaN, GaAs, etc., on which the epitaxial structure is grown.

Referring to FIG. 30, step 2 includes forming a mesa structure by patterning the epitaxial structure.

Herein, the epitaxial structure is etched from top down by a conventional plasma etching process.

Referring to FIG. 31, step 3 includes forming a first mask pattern R1 on the semiconductor substrate 00′ to cover the sidewall of the first type epitaxial layer 01 and the sidewall of the light emitting layer 03.

Herein, the first mask pattern R1 is formed by a conventional photolithography process. The first mask pattern R1 is formed covering the sidewall of the light emitting layer 03, the whole sidewall and the top of the first type epitaxial layer 01.

Referring to FIG. 32, step 4 includes depositing a first dielectric layer 051 on the semiconductor substrate 00′ between the adjacent mesa structures, the top of the first dielectric layer 051 is aligned with the bottom of the light emitting layer 03.

Herein, the first dielectric layer 051 is deposited on the semiconductor substrate 00′ and on the surface of the mask pattern R1 by a conventional vapor deposition process under the protection of the first mask pattern R1. The top of the first dielectric layer 051 is aligned with the bottom of the light emitting layer 03.

In some embodiments, herein the bottom of the first mask pattern R1 is aligned with the bottom of the light emitting layer 03, so the dielectric layer 051 is formed on the whole sidewall of the second type epitaxial layer 02, then the re-growth layer 04 is formed on the whole sidewall of the light emitting layer 03 and the sidewall of the first type epitaxial layer 02.

In another embodiment, the bottom of the first mask pattern R1 is lower than the bottom of the light emitting layer 03, so the top of the first dielectric layer 051 is lower than the top of the second type epitaxial layer 02, then the re-growth layer 04 can be formed on the sidewall of first type epitaxial layer 01, the whole sidewall of the light emitting layer 03 and part of the sidewall of the second type epitaxial layer 02. Therefore, the position of the re-growth layer 04 is decided by the bottom of the first mask pattern R1.

Then, the first mask pattern R1 is removed by a chemical etching process.

Referring to FIG. 33, step 5 includes forming a re-growth layer 04 on the whole sidewall of the light emitting layer 03 and on at least part of the sidewall of the first epitaxial layer 01 by an epitaxial material re-growth process.

Herein, the re-growth layer 04 is directly grown on the whole sidewall of the light emitting layer 03, on the top and the whole sidewall of the first type epitaxial layer 01, and deposited on the top surface of first dielectric layer 051. In this re-growth process, the temperature is 400° C. to 1000° C., and the re-growth time is 5 seconds to 1000 seconds. The material for re-growth process is the same as the material of the first type epitaxial layer and/or the material of the second type epitaxial layer but without intentional extrinsic doping ions. In some embodiments, the re-growth layer 04 is further formed at least part of the sidewall of the second type epitaxial layer 02 when the top of the first dielectric layer 051 is lower than the bottom of the light emitting layer.

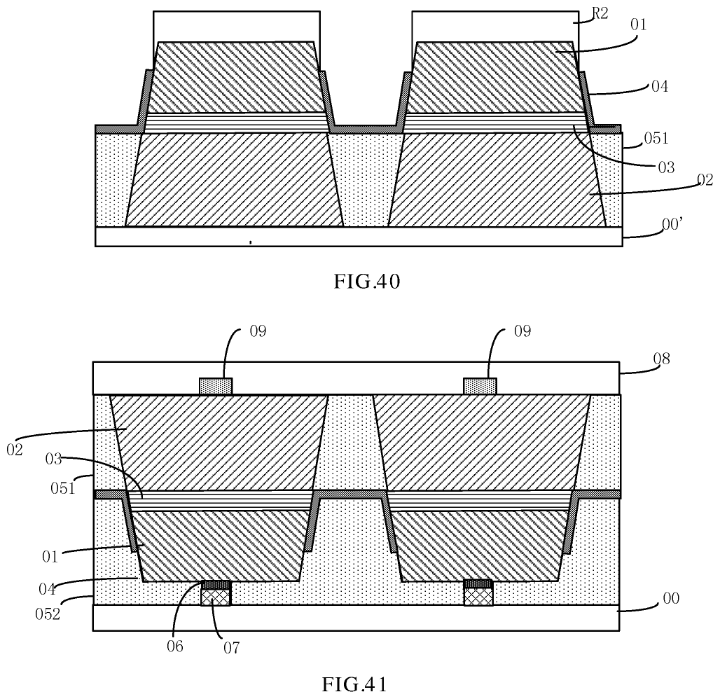

FIG. 40 is a sectional structure of another alternative step 6 according to embodiment 4 of the present invention.

FIG. 41 is a sectional structure diagram of another micro LED structure according to some embodiments (for example, an alternative embodiment 4) of the present invention.

In another embodiment, referring to FIG. 40, in step 6, before forming the re-growth layer 04, step 6 further includes: forming a second mask pattern R2 covering the top and part of the sidewall of the first type epitaxial layer 01; forming the re-growth layer 04 at the whole sidewall of the light emitting layer 03 and part of the sidewall of the first type epitaxial layer 01; after forming the re-growth layer 04, removing the second mask pattern R2. Thus, Referring to FIG. 41, the re-growth layer 04 can be formed on part of the first type epitaxial layer 01, and on the whole sidewall of the light emitting layer 03. Therefore, the position of the re-growth layer 04 is decided by the bottom position of the second mask pattern R2.

Referring to FIG. 36, step 7 includes forming a bottom contact 06 in the re-growth layer 04 on the top surface of the first type epitaxial layer 01 and forming a second dielectric layer 02 on the re-growth layer 04 with an opening exposing the top of the bottom contact 06.

Herein, referring to FIG. 34, a first opening is formed in the re-growth layer 04 on the top surface of the first type epitaxial layer 01 by a plasma etching process; then, referring to FIG. 35, the bottom contact 06 is firstly deposited into the opening with a mask covering the other regions except for the first opening; the bottom contact 06 is connected to the first type epitaxial layer 01, and then the mask is removed; next, referring to FIG. 36, second dielectric layer 052 is deposited on the surface of the re-growth layer 04 by a conventional chemical vapor deposition process; then, another opening is formed in the second dielectric layer 052 to expose the top of the bottom contact 06.

In another embodiment, step 7 includes: forming a second dielectric layer on the re-growth layer and forming an opening in the second dielectric layer on the first type epitaxial layer; and, filling a bottom contact in the opening. Herein, the second dielectric layer is deposited on the surface of the re-growth layer by a conventional chemical vapor deposition process; then, an opening is formed in the second dielectric layer and in the re-growth layer on the top of the first type epitaxial layer; next, the bottom contact is deposited into the opening and connected to the first type epitaxial layer.

In another embodiment, step 7 includes forming the bottom contact 06 before depositing the re-growth layer 04; then, depositing the re-growth layer 04 on the sidewall of the light emitting layer 03, the sidewall and the top of the first type epitaxial layer 01 and on the bottom contact 06; next, forming the second dielectric layer 052 on the re-growth layer 04; finally, forming an opening in the second dielectric layer 052 and the re-growth layer 04, to expose the bottom contact 06.

Referring to FIG. 37, step 8 includes forming a bottom connected structure 07 in the opening.

Herein, the material of the bottom connected structure 07 is deposited into the opening and on the bottom contact by a conventional vapor deposition process.

Referring to FIG. 38, step 9 includes bonding the bottom connected structure 07 with an IC backplane 00 by turning the semiconductor substrate 00′ upside down, then, removing the semiconductor substrate 00′.

Herein, the semiconductor substrate 00′ with the epitaxial structure is firstly turned upside down; then, the bottom connected structure 07 is bonded with a pad of the IC backplane 00. After the bonding process, the semiconductor substrate 00′ is removed by a conventional removing process, such as a laser lift-off method.

Referring to FIG. 39, step 10 includes forming a top contact 09 and a top conductive layer 08 on the second epitaxial layer 02.

Herein, the top contact 09 is deposited on the top of the second type epitaxial layer 02 with a mask protecting the other region; then, a top conductive layer 08 is deposited on the second epitaxial layer 02 by a conventional vapor deposition process.

In some embodiments, herein the dielectric layer in FIG. 28 is formed by the first dielectric layer 051 and the second dielectric layer 052 in FIG. 39.

Another method of manufacturing the aforementioned micro LED panel in embodiment 4, comprises the following steps.

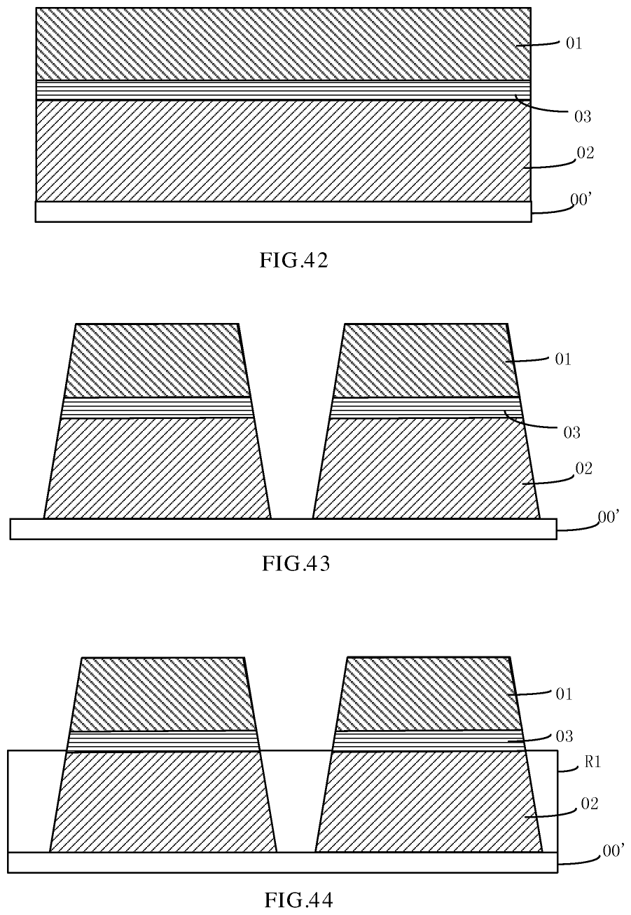

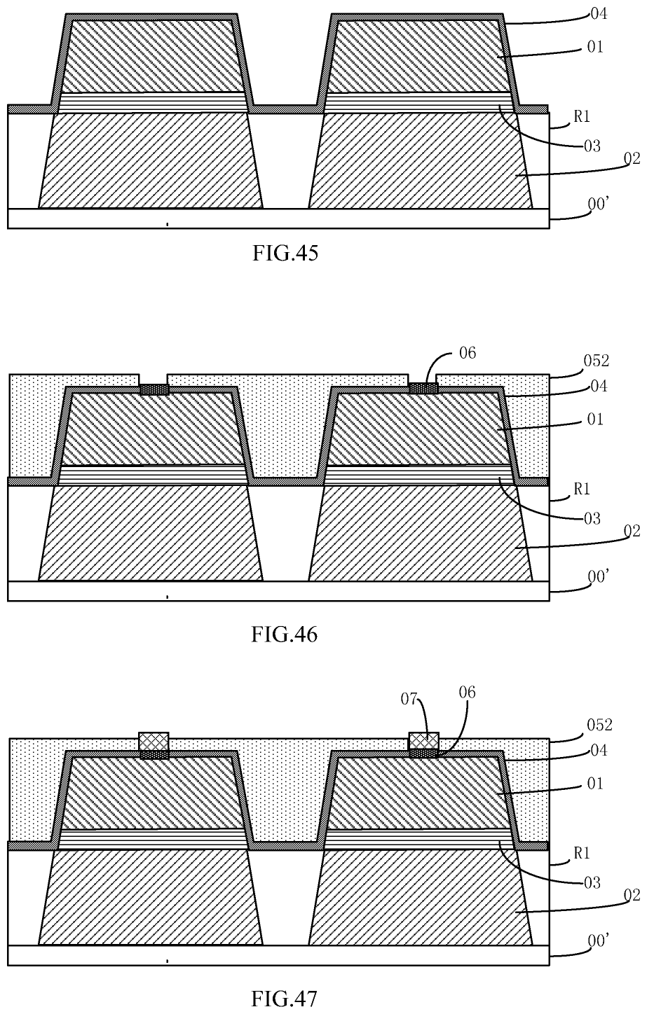

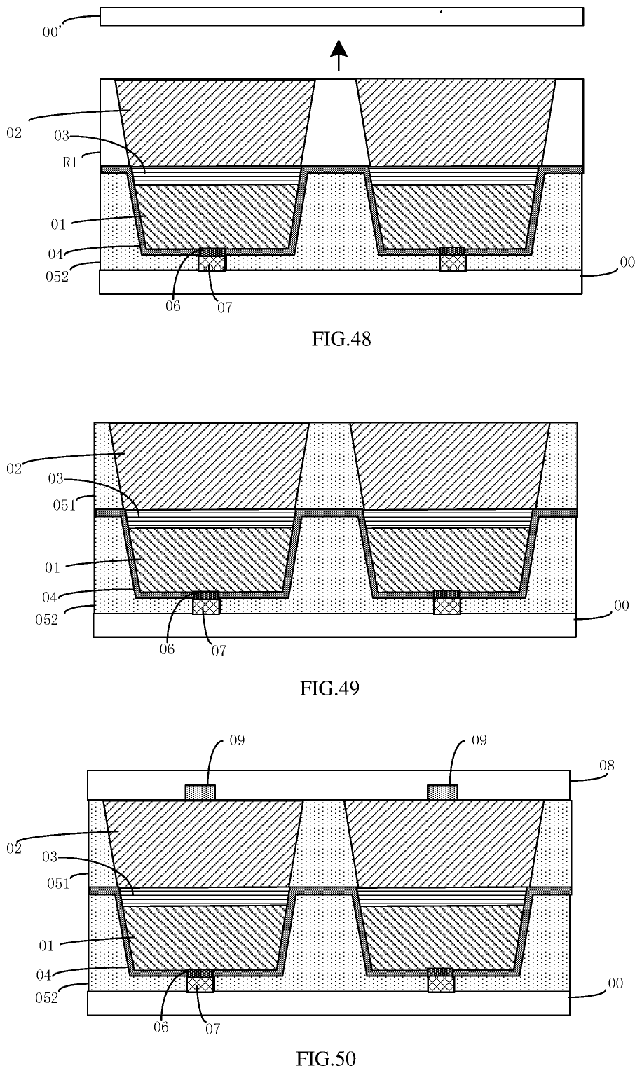

FIGS. 42˜50 illustrate the steps of another alternative method for manufacturing the micro LED structure in FIG. 28.

Referring to FIG. 42, step 1 includes supplying a semiconductor substrate 00′ with an epitaxial structure.

Herein, the epitaxial structure includes a first type epitaxial layer 01, a light emitting layer 03 and a second type epitaxial layer 02 from top down. The material of the semiconductor substrate 00′ can be GaN, GaAs, etc., on which the epitaxial structure is grown.

Referring to FIG. 43, step 2 includes forming a mesa structure by patterning the epitaxial structure.

Herein, the epitaxial structure is etched from top down by a conventional plasma etching process.

Referring to FIG. 44, step 3 includes forming a first mask pattern R1 on the semiconductor substrate 00′ to cover the sidewall of the second type epitaxial layer 02. The top of the first mask pattern R1 is not higher than the bottom of the light emitting layer 03.

Herein, the first mask pattern R1 is formed on the semiconductor substrate 00′ and covers the sidewall of the second type epitaxial layer 02 by a conventional photolithography process. The top of the first mask pattern R1 is aligned with the bottom of the light emitting layer 03. In some embodiments, the top of the first mask pattern R1 is lower than the bottom of the light emitting layer 03 and the re-growth layer 04 can be formed on part of the sidewall of the second type epitaxial layer 02.

Referring to FIG. 45, step 4 includes forming a re-growth layer 04 on the sidewall of the light emitting layer 03 and on at least part of the sidewall of the first epitaxial layer 01 by an epitaxial material re-growth process.

Herein, the re-growth layer 04 is directly grown on the whole sidewall of the light emitting layer 03, on the top and the whole sidewall of the first type epitaxial layer 01, and deposited on the top surface of first mask pattern R1. In this re-growth process, the temperature is 400° C. to 1000° C., and the re-growth time is 5 seconds to 1000 seconds. The material for re-growth process is the same as the material of the first type epitaxial layer and/or the material of the second type epitaxial layer but without intentional extrinsic doping ions. In some embodiments, the re-growth layer 04 is further formed at least part of the sidewall of the second type epitaxial layer 02 when the top of the first mask pattern R1 is lower than the bottom of the light emitting layer 03.

In another embodiment, in step 4, before the re-growth layer 04 growing, step 4 further includes: forming a second mask pattern covering the top and part of the sidewall of the first type epitaxial layer 01. The re-growth layer 04 is formed at the whole sidewall of the light emitting layer 03 and part of the sidewall of the first type epitaxial layer 01. After forming the re-growth layer 04, step 4 further includes: removing the second mask pattern. Thus, the re-growth layer 04 can be formed on part of the first type epitaxial layer 01, and on the whole sidewall of the light emitting layer 03.

Referring to FIG. 46, step 5 includes forming a dielectric layer 052 on the re-growth layer 04 and forming an opening on the first type epitaxial layer 01, and, forming a bottom contact 06 in the opening.

Herein, the dielectric layer 052 is deposited on the surface of the re-growth layer 04 by a conventional chemical vapor deposition process; then, an opening is formed in the dielectric layer 052 and in the re-growth layer 04 on the top of the first type epitaxial layer 01; next, the bottom contact 06 is deposited into the opening and connected to the first type epitaxial layer 01.

In some embodiments, the step 5 comprises the following steps: firstly, forming a first opening in the re-growth layer 04 on the top of the first type epitaxial layer 01; then, depositing the bottom contact 06 in the first opening with a mask covering the other regions except for the first opening, and removing the mask; next, depositing the dielectric layer 052 on the re-growth layer 04 and the bottom contact 06; then, forming a second opening in the dielectric layer 052 on the first opening, to expose the bottom contact 06.

In another embodiment, step 5 includes: forming the bottom contact 06 before depositing the re-growth layer 04; then, depositing the re-growth layer 04 on the sidewall of the light emitting layer 03, the sidewall and the top of the first type epitaxial layer 01 and on the bottom contact 06; next, forming the second type epitaxial layer 02 on the re-growth layer 04; finally, forming an opening in the second type epitaxial layer 02 and the re-growth layer 04, to expose the bottom contact 06.

Referring to FIG. 47, step 8 includes forming a bottom connected structure 07 in the opening.

Herein, the material of the bottom connected structure 07 is deposited into the opening and on the bottom contact 06 by a conventional vapor deposition process.

Referring to FIG. 48, step 9 includes bonding the bottom connected structure 07 with an IC backplane 00 by turning the semiconductor substrate 00′ upside down, then, removing the semiconductor substrate 00′.

Herein, the semiconductor substrate 00′ with the epitaxial structure is firstly turned upside down; then, the bottom connected structure 07 is bonded with a pad of the IC backplane 00; after the bonding process, the semiconductor substrate 00′ is removed by a conventional removing process, such as a laser lift-off method.

Referring to FIG. 49, step 10 includes forming another dielectric layer 051 on the re-growth layer 04 and between the adjacent mesa structures.

Herein, another dielectric layer 051 is deposited on the re-growth layer 04 by a conventional chemical vapor deposition method.

Referring to FIG. 50, Step 11 includes forming a top contact 09 and a top conductive layer 08 on the second epitaxial layer 02.

Herein, the top contact 09 is deposited on the top of the second type epitaxial layer 02 with a mask protecting the other region, and then the mask is removed; finally, a top conductive layer 08 is deposited on the second epitaxial layer 02 by a conventional vapor deposition process.

It is understood by those skilled in the art that, the micro display panel is not limited by the structure mentioned above, and may include more or less components than those as illustrated, or some components may be combined, or a different component may be utilized.

It is understood by those skilled in the art that, all or part of the steps for implementing the foregoing embodiments may be implemented by hardware, or may be implemented by a program which instructs related hardware. The program may be stored in a flash memory, in a conventional computer device, in a central processing module, in an adjustment module, etc.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-50 combined or otherwise re-arranged in various other embodiments.

Although the detailed description contains many specifics, these should not be construed as limiting the scope of the invention but merely as illustrating different examples and aspects of the invention. It should be appreciated that the scope of the invention includes other embodiments not discussed in detail above. For example, the approaches described above can be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present invention can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present invention can be incorporated in software and/or firmware for controlling the hardware of a processing system, and for enabling a processing system to interact with other mechanisms utilizing the results of the present invention. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the invention and the various embodiments.

1. A micro LED panel having a micro LED array, comprising a plurality of micro LED structures, wherein each of the plurality of micro LED structures comprises:
a mesa structure, comprising a first type epitaxial layer and a light emitting layer from bottom to top;
a second type epitaxial layer, formed on a top of the light emitting layer, the second type epitaxial layer of the plurality of micro LED structures being continuously formed on a whole area of the micro LED panel; and
a re-growth layer, grown on at least a part of a sidewall of the first type epitaxial layer and a whole of a sidewall of the light emitting layer.

2. The micro LED panel according to claim 1, further comprising a dielectric layer, formed between adjacent mesa structures of the plurality of micro LED structures, wherein:
a top end of the re-growth layer further extrudes along a top surface of the dielectric layer; and
the second type epitaxial layer is formed on the top of the light emitting layer and the top end of the re-growth layer.

3. The micro LED panel according to claim 2, wherein:
the re-growth layer on the sidewall of the light emitting layer is not parallel to an extending direction of the light emitting layer, and an inclined angle of the re-growth layer on the sidewall of the light emitting layer is about 30 degrees to about 90 degrees relative to the extending direction of the light emitting layer; and
the re-growth layer extruded along the dielectric layer is parallel to a top surface of the dielectric layer.

4. (canceled)

5. The micro LED panel according to claim 2, wherein the re-growth layer extruded along the top surface of the dielectric layer is connected between adjacent light emitting layers of the plurality of micro LED structures.

6. The micro LED panel according to claim 1, wherein the re-growth layer is further formed on a whole of the sidewall of the first type epitaxial layer.

7. The micro LED panel according to claim 6, wherein the re-growth layer is further formed on a bottom surface of the first type epitaxial layer.

8. The micro LED panel according to claim 1, wherein a diameter of the mesa structure is less than or equal to about 3 μm.

9. The micro LED panel according to claim 1, wherein:
the light emitting layer comprises a top surface, an edge surface, and a bottom surface;
the re-growth layer is grown on the edge surface of the light emitting layer; and
the re-growth layer is not grown on the top surface and the bottom surface of the light emitting layer.

10. The micro LED panel according to claim 1, wherein:
the light emitting layer comprises a plurality of pairs of quantum wells; and
the re-growth layer on the sidewall of the light emitting layer is not parallel to each of the plurality of pairs of quantum wells.

11. The micro LED panel according to claim 1, wherein a cross section of the light emitting layer has a straight line shape without any bending.

12. The micro LED panel according to claim 1, wherein:
a material of the re-growth layer with intrinsic doped ions is the same as a material of the first type epitaxial layer or a material of the second type epitaxial layer; and
the material of the re-growth layer does not include extrinsic doping ions.

13. The micro LED panel according to claim 12, wherein a material of the re-growth layer is one or more of GaP, AlP, GaAs, InP, AlInP, GaInP, AlN, GaN, and/or InN.

14. The micro LED panel according to claim 1, wherein;
a material of the re-growth layer is monocrystal;
a material of the first type epitaxial layer is monocrystal; and
a material of the second type epitaxial layer is monocrystal.

15. The micro LED panel according to claim 1, wherein a band gap of the re-growth layer is greater than a band gap of the light emitting layer.

16. The micro LED panel according to claim 1, wherein;
a thickness of the re-growth layer is less than a thickness of the light emitting layer; and
the thickness of the re-growth layer is less than or equal to about 100 nm.

17. (canceled)

18. The micro LED panel according to claim 1, wherein:
resistance of the re-growth layer is higher than resistance of the light emitting layer; and
the re-growth layer is not electrically conductive.

19. (canceled)

20. The micro LED panel according to claim 2, wherein a material of the dielectric layer is one or more of SiO₂, SiNₓ, Al₂O₃, AlN, HfO₂, TiO₂, and/or ZrO₂.

21. The micro LED panel according to claim 1, wherein;
a material of the first type epitaxial layer is one or more of GaAs, InGaAs, GaP, GaN, InGaN, AlGaN, AlInP, GaInP, and/or AlGaInP; and
a material of the second type epitaxial layer is one or more of GaAs, InGaAs, GaP, GaN, InGaN, AlGaN, AlInP, GaInP, and/or AlGaInP.

22-92. (canceled)

93. The micro LED panel according to claim 1, wherein:
a top contact is formed on top of the second type epitaxial layer; and
a top conductive layer is formed on top of the top contact.

94. The micro LED panel according to claim 1, wherein:
a bottom contact is formed at a bottom surface of the first type epitaxial layer; and
a bottom connected structure is formed at a bottom of the bottom contact, configured to be bonded with an IC backplane.
